(19) United States
(12) Patent Application Publication
(10) Pub. No.: US 2026/0273839 A1
(43) Pub. Date: Sep. 17, 2026

(54) METHODS AND SYSTEMS FOR FORMING A THREE-DIMENSIONAL OBJECT AND METHODS FOR GENERATING A SCALED DIGITAL MODEL FOR PRINTING A THREE-DIMENSIONAL OBJECT

(71) Applicant: QUADRATIC 3D, INC., CHARLESTOWN, MA (US)

(72) Inventors: SAMUEL N. SANDERS, ARLINGTON, MA (US); SARAH K. POOLE, CAMBRIDGE, MA (US); GAVIN R. KIEL, CAMBRIDGE, MA (US)

(21) Appl. No.: 19/678,114

(22) Filed: May 14, 2026

Related U.S. Application Data
(63) Continuation of application No. PCT/US2024/056258, filed on Nov. 15, 2024.
(60) Provisional application No. 63/599,243, filed on Nov. 15, 2023.

(51) Int. Cl. B29C 64/135; B29C 64/393; B33Y 10/00; B33Y 50/02

(52) U.S. Cl. CPC B29C 64/135; B29C 64/393; B33Y 10/00; B33Y 50/02

(57) ABSTRACT

Methods and systems including a scaled digital model for forming a three-dimensional object in a volume of a photohardenable composition, the method including at least two excitation lights, and methods for generating a scaled digital model for printing a three-dimensional (3D) object. In one aspect, a method can include an arrangement of illuminated pixels wherein each pixel in the arrangement has an intensity level that is scaled such that a cross-linking or polymerization reaction of the photohardenable composition resulting from exposure to optical image and light sheet at the selected location occurs at a rate that is substantially homogeneous. In another aspect, generating a scaled model of each digital slice of the object to be printed includes assigning an intensity level to each pixel to be illuminated with an excitation light based on one or more factors including the position in an arrangement of each pixel to be illuminated with the excitation light relative to one or more propagating rays of the other excitation light to which the pixel will be exposed during printing of the scaled digital slice. Methods for improving cure homogeneity in printing a 3D object are also disclosed.

### CROSS-REFERENCE TO RELATED APPLICATIONS

This application is a continuation of International Application No. PCT/US2024/056258 filed Nov. 15, 2024, which International Application claims priority to U.S. Provisional Patent Application No. 63/599,243 filed on Nov. 15, 2023. Each of the foregoing applications is hereby incorporated herein by reference in its entirety for all purposes.

### TECHNICAL FIELD OF THE INVENTION

The present relates to the technical field of three-dimensional printing and related methods and systems.

### BRIEF SUMMARY OF THE INVENTION

The present invention includes methods and systems including a scaled model for forming an object in a volume of a photohardenable composition, methods for generating a scaled digital model for printing a three-dimensional (3D) object, and methods for improving cure rate homogeneity in printing a 3D object.

In accordance with one aspect of the present invention there is provided a method for producing a three-dimensional object, the method comprising:
a) providing a volume including a photohardenable composition comprising a photohardenable component and a dual wavelength photoinitiator;
b) exposing a selected location in the photohardenable composition to at least two excitation lights, the at least two excitation lights including a light sheet including a first excitation light comprising a first wavelength and an optical image including a second excitation light comprising a second wavelength, wherein the optical image comprises an arrangement including illuminated pixels and non-illuminated pixels, wherein each illuminated pixel in the arrangement has an intensity level that is scaled such that a cross-linking or polymerization reaction of the photohardenable composition resulting from exposure to the optical image and the light sheet at the selected location occurs at a rate that is substantially homogeneous; and optionally c) repeating step b) one or more times wherein, for a repeated step, one or both of the selected location and optical image is the same as or different from a previous selected location and/or a previous optical image, and the intensity assigned to each illuminated pixel in the arrangement of a repeated step is assigned on a repeated step by repeated step basis.

In accordance with another aspect of the present invention there is provided a method for producing a three-dimensional (3D) object with use of a 3D printer including at least two excitation lights including a first excitation light and a second excitation light, the method comprising:
a) providing a volume including a photohardenable composition comprising a photohardenable component and a dual wavelength photoinitiator wherein exposure of the photohardenable composition to a first excitation light including a first wavelength and a second excitation light including a second wavelength induces a crosslinking or polymerization reaction in the photohardenable composition;
b) generating a scaled model of two-dimensional cross-sectional digital slices of the 3D object to be printed, wherein each cross-sectional digital slice includes an arrangement including pixels to be illuminated and pixels not to be illuminated during printing of the slice, and wherein generating the scaled model of the digital slice comprises assigning an intensity level to each pixel to be illuminated with the second excitation light based on at least the position in the arrangement of each pixel to be illuminated with the second excitation light relative to one or more propagating rays of the first excitation light to which the pixel will be exposed during printing of the scaled digital slice;
c) exposing a selected two-dimensional cross-sectional plane in the volume of the photohardenable composition to at least a light sheet including the first excitation light comprising the first wavelength and an optical image including the second excitation light comprising second wavelength to form a cross-sectional slice of the 3D object, wherein the optical image comprises a two-dimensional cross-sectional slice of the 3D object generated from a scaled digital slice of the 3D object; and
optionally d) repeating step c) one or more times wherein, for a repeated step, one or both of the selected location and optical image is the same as or different from a previous selected location and/or a previous optical image.

In accordance with another aspect of the present invention there is provided a method for producing a three-dimensional (3D) object with use of a 3D printer including at least two excitation lights including a first excitation light and a second excitation light, the method comprising:
a) obtaining a digital model corresponding to at least a portion of the 3D object;
b) slicing the digital model to generate a plurality of digital slices corresponding to slices, e.g., sequential slices, of the digital model for use in generating computer instructions for printing by the 3D printer, each slice including a two-dimensional cross-sectional slice of the 3D object (e.g., in an x-y plane), each slice including an arrangement including pixels to be illuminated and pixels not to be illuminated during printing of the slice;
c) generating a scaled model of each digital slice comprising assigning an intensity level to each pixel to be illuminated with the second excitation light based on at least the position in the arrangement of each pixel to be illuminated with the second excitation light relative to one or more propagating rays of the first excitation light to which the pixel will be exposed during printing of the scaled digital slice;
d) exposing a selected two-dimensional cross-sectional plane in a volume of a photohardenable composition including a dual-wavelength photoinitiator to at least a light sheet including the first excitation light comprising a first wavelength and an optical image including the second excitation light comprising a second wavelength to form a cross-sectional slice of the 3D object, wherein the optical image comprises a two-dimensional cross-sectional slice of the 3D object generated from a scaled digital slice of the 3D object; and
optionally e) repeating step d) one or more times wherein, for a repeated step, one or both of the selected location and optical image is the same as or different from a previous selected location and/or a previous optical image.

In accordance with another aspect of the present invention there is provided a method for producing a three-dimensional (3D) object with use of a 3D printer including at least two excitation lights including a first excitation light and a second excitation light, the method comprising:
a) providing a volume including a photohardenable composition comprising a photohardenable component and a dual wavelength photoinitiator;
b) slicing a digital model corresponding to at least a portion of the 3D object into a plurality of two-dimensional slices, e.g., slices, of the digital model of the 3D object (e.g., in an x-y plane), each digital slice including an arrangement including pixels to be illuminated by the second excitation light during printing of a slice and pixels not to be illuminated by the second excitation light during printing of the slice;
c) generating a scaled model of each digital slice wherein each pixel in a digital slice to be illuminated with the second excitation is assigned an intensity level based on at least its position in the arrangement relative to one or more propagating rays of the first excitation light to which the pixel will be exposed during printing of the scaled digital slice;
d) exposing a selected two-dimensional cross-sectional plane in the volume of the photohardenable composition to at least a light sheet including a first excitation light comprising a first wavelength and an optical image including a second excitation light comprising a second wavelength to form a cross-sectional slice of the 3D object, wherein the optical image comprises the scaled digital slice corresponding to the selected two-dimensional cross-sectional slice of the 3D object generated from the scaled model of the 3D object; and
optionally e) repeating step d) one or more times wherein, for a repeated step one or both of the two-dimensional cross-sectional plane in the volume and the optical image is the same as or different from a previous selected two-dimensional cross-sectional plane in the volume and/or a previous optical image.

In accordance with another aspect of the present invention there is provided a method for generating a scaled digital model for printing a three-dimensional (3D) object with at least a first excitation light including a first wavelength and a second excitation light including a second wavelength, the method comprising:
generating a scaled digital model of two-dimensional cross-sectional digital slices of the 3D object comprising assigning an intensity level to each pixel to be illuminated with the second excitation light, wherein a digital slice includes an arrangement including pixels to be illuminated by the second excitation light during printing of a slice and pixels not to be illuminated by the second excitation light during printing of the slice, and wherein the assignment of the intensity level is based on at least the position of the pixel to be illuminated in the arrangement relative to one or more propagating rays of the first excitation light to which the pixel will be exposed during printing of the scaled digital slice and taking into account the number of illuminated pixels in a path of the one or more propagating light rays of the first excitation light between the pixel and the end of the path traversed by the one or more propagating light rays in the arrangement.

In accordance with another aspect of the present invention there is provided a method for generating a scaled digital model for printing a three-dimensional (3D) object with at least a first excitation light including a first wavelength and a second excitation light including a second wavelength, the method comprising:
a) obtaining a digital model corresponding to at least a portion of the 3D object;
b) slicing the digital model to generate a plurality of digital slices corresponding to the digital model for use in generating computer instructions for printing by a 3D printer, each slice including a two-dimensional cross-sectional slice of the 3d object (e.g., in an x-y plane), each slice including an arrangement including pixels to be illuminated during printing of the slice and pixels not to be illuminated by the second excitation light during printing of the slice;
c) generating a scaled digital model of each digital slice comprising assigning an intensity level to each pixel in a digital slice to be illuminated with the second excitation light during printing to provide a scaled digital model of each two-dimensional cross-sectional slice of the 3D object to be printed, wherein the assignment of the intensity level is based on at least the position in the arrangement of each pixel to be illuminated with the second excitation light relative to one or more propagating light rays of the first excitation light to which the pixel will be exposed during printing of the scaled digital slice.

In accordance with another aspect of the present invention there is provided a method for generating a scaled digital model for printing a three-dimensional (3D) object with at least a first excitation light including a first wavelength and a second excitation light including a second wavelength, the method comprising:
a) obtaining a digital model corresponding to at least a portion of the 3D object and slicing the digital model into a plurality of two-dimensional slices of the digital model of the 3D object (e.g., in an x-y plane), each slice including an arrangement including pixels to be illuminated by the second excitation light and pixels not to be illuminated by the second excitation light during printing of the scaled digital slice; and
b) generating a scaled digital model of each digital slice comprising assigning an intensity level to each pixel of a digital slice to be illuminated with the second excitation light based on at least its position in the arrangement relative to one or more propagating rays of the first excitation light to which the pixel will be exposed during printing of the scaled digital slice and taking into account the number of illuminated pixels in the path of the one or more propagating light rays of the first excitation light between the pixel and the end of the path traversed by the one or more propagating light rays in the arrangement.

In accordance with another aspect of the present invention there is provided a system comprising:

a container capable of holding a volume of a photohardenable composition, wherein the container is adapted for passage of excitation light into the container;

two optical systems including a first optical system for generating and projecting a light sheet for generating and directing a light sheet comprising a first excitation light including a first wavelength to a selected location in the container and a second optical system for generating and projecting an optical image comprising an arrangement including illuminated pixels including a second excitation light including a second wavelength and non-illuminated pixels to a selected location in the photohardenable composition preferably such that the optical image and light sheet overlap in a common plane at the selected location; and
a controller to control the printing of a 3D object, wherein the controller is configured to perform operations comprising:

generating a scaled model of optical images corresponding to two-dimensional cross-sectional digital slices of the 3D object comprising assigning an intensity level to each pixel to be illuminated with the second excitation light including the second wavelength based on at least the position in the arrangement of each pixel to be illuminated with the second excitation light relative to one or more propagating rays of the first excitation light to which the pixel will be exposed during printing of the scaled digital slice; and
controlling the optical system for directing the optical image to the selected location in the photohardenable composition based on the scaled digital slice information and directing the light sheet to the selected location in the photohardenable composition.

In accordance with another aspect of the present invention there is provided a method for improving cure rate homogeneity across a light sheet traversal direction through a photohardenable composition, the method comprising:
a) obtaining a digital model corresponding to at least a portion of a 3D object;
b) slicing the digital model to generate a plurality of digital slices corresponding to the digital model for use in generating computer instructions for printing by a 3D printer, each slice including a two-dimensional cross-sectional slice of the 3D object (e.g., in an x-y plane), each slice including an arrangement including pixels to be illuminated and pixels not to be illuminated during printing of the slice;
c) generating a scaled model of each digital slice comprising assigning an intensity level to each pixel to be illuminated with the second excitation light based on at least the position in the arrangement of each pixel to be illuminated with the second excitation light relative to one or more propagating rays of the first excitation light to which the pixel will be exposed during printing of the scaled digital slice;
d) exposing a selected two-dimensional cross-sectional plane in a volume of the photohardenable composition, wherein the photohardenable composition includes a dual-wavelength photoinitiator, to at least a light sheet including a first excitation light comprising a first wavelength and an optical image including a second excitation light comprising a second wavelength to form a cross-sectional slice of the 3D object, wherein the optical image comprises a two-dimensional cross-sectional slice of the 3D object generated from a scaled digital slice of the 3D object; and
optionally e) repeating step d) one or more times wherein, for a repeated step, one or both of the selected location and optical image is the same as or different from a previous selected location and/or a previous optical image.
wherein the cure rate across a light sheet traversal direction through the photohardenable composition of the cross-sectional slices of the 3D object being printed is more homogeneous than printing without use of the scaled digital slices.

In accordance with another aspect of the present invention there is provided a method for improving cure rate homogeneity across a light sheet traversal direction through a photohardenable composition, the method comprising:
a) providing a volume including the photohardenable composition, wherein the photohardenable composition includes a dual wavelength photoinitiator;
b) slicing a digital model corresponding to at least a portion of a 3D object into a plurality of two-dimensional sequential slices of the digital model of the 3D object (e.g., in an x-y plane), each digital slice including an arrangement including pixels to be illuminated by the second excitation light during printing of a slice and pixels not to be illuminated by the second excitation light during printing of the slice;
c) generating a scaled model of each digital slice wherein each pixel in a digital slice to be illuminated with the second excitation is assigned an intensity level based on at least its position in the arrangement relative to one or more propagating rays of the first excitation light to which the pixel will be exposed during printing of the scaled digital slice;
d) exposing a selected two-dimensional cross-sectional plane in the volume of the photohardenable composition to at least a light sheet including a first excitation light comprising a first wavelength and an optical image including a second excitation light comprising a second wavelength to form a cross-sectional slice of the 3D object, wherein the optical image comprises the scaled digital slice corresponding to the selected two-dimensional cross-sectional slice of the 3D object generated from the scaled model of the 3D object; and
optionally e) repeating step c) one or more times wherein, for a repeated step one or both of the two-dimensional cross-sectional plane in the volume and the optical image is the same as or different from a previous selected two-dimensional cross-sectional plane in the volume and/or a previous optical image,
wherein the cure rate across a light sheet traversal direction through the photohardenable composition of the cross-sectional slices of the 3D object being printed is more homogeneous than printing without use of the scaled digital slices.

The attached figures are simplified representations presented for purposes of illustration only; the actual structures may differ in numerous respects, particularly including the relative scale of the articles depicted and aspects thereof.

The foregoing, and other aspects and embodiments described herein and contemplated by this disclosure all constitute embodiments of the present invention.

It should be appreciated by those persons having ordinary skill in the art(s) to which the present invention relates that any of the features described herein in respect of any particular aspect and/or embodiment of the present invention can be combined with one or more of any of the other features of any other aspects and/or embodiments of the present invention described herein, with modifications as appropriate to ensure compatibility of the combinations. Such combinations are considered to be part of the present invention contemplated by this disclosure.

It is to be understood that both the foregoing general description and the following detailed description are exemplary and explanatory only and are not restrictive of the invention as claimed.

Other embodiments will be apparent to those skilled in the art from consideration of the description, from the claims, and from practice of the invention disclosed herein.

### BRIEF DESCRIPTION OF THE DRAWINGS

In the drawings,

FIG. 1 provides examples of photoswitchable photoinitiators useful in the method of the present invention with absorption spectra therefor.

FIG. 2 depicts an example of a flow chart for preferred methods of the present invention.

FIG. 3 provides an example of code for counting “on” pixels along a row and using this input to modify the gray values of the projected image.

FIGS. 4A and 4C depict example two-dimensional cross-sectional slices of an object before assignment of intensity levels in accordance with the present invention; and FIGS. 4B and 4D depict example two-dimensional cross-sectional slices of shown in FIGS. 4A and 4C, respectively, after assignment of intensity levels in accordance with the present invention to modify the pixel gray value based on cumulative “on” pixels in a row.

FIGS. 5A-5F illustrate examples showing implementation of a row-wise grayscale algorithm where a “row” of pixels corresponds to the path of a light sheet ray generated with use of a compression lens.

FIG. 6 illustrates how the variable gray is a continuous function of the “on” pixel count variable, count. Count is not necessarily an integer but could be a fraction if counting partially on (gray) pixels. In this figure, three exemplary relationships between pixel count and gray value are shown, such as a linear relationship, an exponential relationship, or even a more complex relationship.

FIG. 7 is a schematic illustration of an example of a system in accordance with the present invention.

For a better understanding to the present invention, together with other advantages and capabilities thereof, reference is made to the following disclosure and appended claims in connection with the above-described drawings.

### DETAILED DESCRIPTION OF THE INVENTION

Various aspects and embodiments of the present inventions will be further described in the following detailed description.

The present invention includes methods and systems including a scaled model for forming an object in a volume of a photohardenable composition, methods for generating a scaled model for printing a three-dimensional (3D) object, and methods for improving cure homogeneity in printing a 3D object.

The present invention is particularly advantageous for use in methods including dual-wavelength 3D printing in which an object is at least partially formed in a volume of a photohardenable composition at the intersection or overlap of a first excitation light including a first wavelength, preferably in the form of a light sheet, and a second excitation light including a second wavelength, preferably in the form of an optical image. Preferably the first and second wavelengths are not the same.

One issue that arises when addressing a photocurable medium with an intersecting or overlapping light sheet and projected optical image is attenuation of the intensity of the light sheet. The light sheet wavelength is attenuated by absorption in the photocurable medium (e.g., photohardenable composition or resin), causing the intensity of light to be reduced as it travels through the photocurable medium from where it enters the photocurable medium (also referred to herein as light sheet entry) to where it exits the photocurable medium (also referred to herein as light sheet exit). A brighter light sheet light will typically lead to faster rates of photopolymerization. The intersection of an attenuated light sheet with the optical image can result in undesirable effect of inhomogeneous cure rates across the light sheet.

One way to improve cure rate homogeneity across the light sheet traversal direction is to modulate the projector brightness. Typically, cure rates will increase when projector light is brighter. Therefore, in places where the light sheet is dimmer, the projector can be made brighter, and the overall cure rate can be normalized across the light sheet. Similarly, in places where light sheet is brighter, projected light can be dimmed.

In accordance with the present invention it has been found that modulation of the brightness of the projected optical image, by applying the same projector brightness gradient to every projected image, is insufficient to treat light sheet attenuation. In accordance with the present invention, it has been found that light sheet attenuation is not the same for every slice.

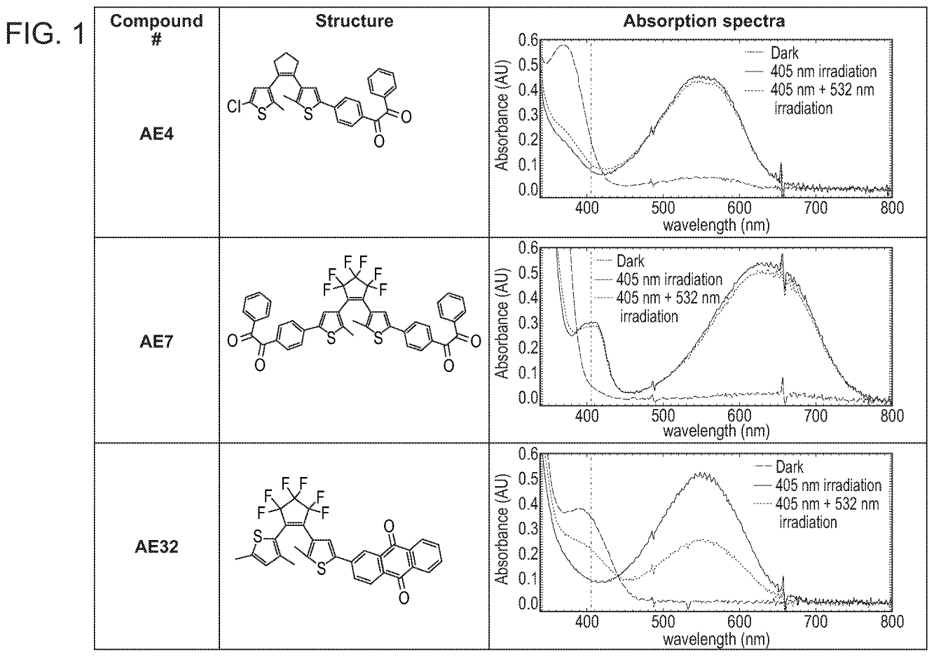

Further, in some photocurable media, the attenuation of the light sheet light is additionally altered by the irradiation of the projector light. In these cases, each projected pixel will cause an increase or decrease in the absorption of propagating light sheet rays at the location of that pixel. FIG. 1 depicts examples of photoswitchable photoinitiators that can be included in photohardenable compositions that may be desirable for use in the methods described herein including photocuring at the intersection of a light sheet and a projected optical image. The three dual wavelength photoswitchable photoinitiators designated in FIG. 1 as AE4, AE7, and AE32 were prepared substantially as described for the respective photoswitchable photoinitiators in the Example section of International Application No. PCT/US2023/022172 of Quadratic 3D, Inc. filed May 13, 2023 for photoswitchable photoinitiators having the same designations.

Additionally, absorption spectra are provided for the depicted dual wavelength photoswitchable photoinitiators in a 1 centimeter cuvette. The spectra shown in FIG. 1 for each of the three examples were measured on samples of each dispersed in a Test Resin at a concentration of 20 parts per million (ppm). The absorption spectra are reported in the absence of illumination (dashed line); in the presence of illumination of the entire region being probed with a first wavelength, 405 nm (solid line), light (a typical wavelength for a light sheet); and in the presence of both the first wavelength, 405 nm, and the second wavelength, 532 nm, (dotted line), light which demonstrates the change in absorption spectrum when the photocurable medium is under various illumination conditions. These spectra demonstrate how absorption at relevant light sheet wavelengths such as, for example, 405 nm can vary with coincident illumination with 532 nm light. As shown in the examples, first wavelength, 405 nm, absorption can either increase (see, e.g., AE4 and AE32) or decrease (see, e.g., AE7) upon illumination with the second wavelength, 532 nm, light (a typical wavelength for projector light).

Following are descriptions of the procedures followed for preparation of a base resin used in preparing a Test Resin, preparation of the Test Resins used in generating the spectra shown in FIG. 1, and the procedure followed for measuring the absorption spectra under continuous single (405 nm) and dual (405 nm+532 nm) wavelength irradiation:

### Base Resin Preparation

A 100-mL round bottom flask containing a magnetic stir bar was charged with 10.0 g of thixotrope (Crystasense HP-5, Croda). To this flask was then added 50.0 g of N, N-dimethylacrylamide (DMAA, Rahn) via syringe. The flask was sealed with a rubber septum and a 1-in 22G needle was inserted for venting. The flask was placed on a preheated (105° C.) aluminum heating block and the mixture was stirred at 250-300 rpm until the thixotrope fully dissolved (10-15 min). Next, a 0.6 gallon polypropylene pail equipped with polypropylene lid was charged with 50.0 g DMAA via syringe. To this pail was then added 200 g of Genomer 4259 (Rahn) and 650 g of Genomer 4247 (Rahn) via large-bore syringe. The contents of the pail were speedmixed (DAC 2800-1000, Flacktek) at 1100 rpm for 1 min. The HP-5 solution was then poured into the pail and the contents of the pail were speedmixed at 1100 rpm for a further 1 min.

### Preparation of Test Resin Including a Photoswitchable Photoinitiator for UV/VIS Absorption Measurements

A stock solution was prepared by dissolving a photoswitchable photoinitiator (AE4, AE7, or AE32) in N, N-dimethylacrylamide (DMAA, Rahn) in a 4 mL amber vial to get a final concentration of 1.00 mg/g of analyte in DMAA. To a 40 mL amber vial containing 29.4 g of Base Resin (described above) was then added 0.60 g of the photoswitchable photoinitiator stock solution to create a resin containing 20 parts per million (by mass) of photoswitchable photoinitiator. This mixture was speedmixed (DAC 2800-1000, Flacktek) at 3500 rpm for 1 min and transferred to 1 cm plastic cuvettes. The cuvettes were capped and centrifuged at 4000 rpm for 3 min to remove trapped air bubbles.

### Measurement of Absorption Spectra Under Continuous Single (405 nm) and DUAL (405 nm+532 nm) Wavelength Irradiation

A commercial Lambda 465 UV/Vis Spectrophotometer (PerkinElmer) was modified to enable high intensity, continuous-wave (CW) external irradiation. Two circular holes, each with an area of 120 mm² , were machined into the cuvette holder to enable entry and exit of an external irradiation source. These holes face each other on opposite sides of the cuvette and are orthogonal to the pre-existing entry and exit holes for the probe, which each have an area of 36 mm² . The two external irradiation sources (405 nm CW GaN laser with 1.1 W operating power and 532 nm CW Nd:YVO4 laser with 2 W operating power) were joined with a bifurcated fiber to produce coaxial beams that were subsequently collimated to an area sufficient to cover the 120 mm² entry and exit holes described above. At the beginning and end of each series of absorption experiments, the irradiance values (0.2 W/cm² for 405 nm and 0.4 W/cm² for 532 nm) were measured at the 120 mm² exit hole of the cuvette holder (in the absence of a cuvette). The spectra presented in Table 1 were acquired as follows. A 1 cm cuvette containing Test Resin (prepared as described above) was placed in the modified cuvette holder, a spectrum was acquired with no external irradiation, then a series of spectra was recorded every 5 seconds under CW 405 nm irradiation (0.2 W/cm² ). Subsequently, with a fresh cuvette, the same series of measurements was performed under simultaneous 405 nm and 532 nm CW irradiation (0.2 W/cm² and 0.4 W/cm² , respectively). The spectra shown in Table 1 are those with the maximum observed absorption values in the series of measurements.

Photohardenable compositions for use in the present invention preferably include dual wavelength photoinitiators. Additional information relating to photohardenable compositions and photoinitiators is provided below.

It has been found that methods described herein for forming a 3D object in a volume of a photohardenable composition including a dual wavelength photoinitiator that includes modification of the intensity levels of the pixels of the optical image taking into account the number of “on” projector pixels traversed by the propagating rays of the intersecting light sheet, especially for photohardenable compositions including dual wavelength photoinitiators for which absorbance of light sheet wavelengths is increased or decreased in the presence of the optical image wavelength, can achieve homogeneous or substantially homogeneous cure rates at the intersection of a projected optical image and a light sheet that experiences attenuation as it passes through the volume.

The parameter of “intensity level” of a pixel occurs in two aspects here. The first is in the software representation of the amplitude of a pixel; its range conventionally is between values easily represented digitally, such as a floating point value between 0 and 1, an integer between 0 and 255, or other ranges. The second is the optical form of intensity, as provided by an imaging system such as a projector of 2-D slices in a 3-D printer.

This direction traversed by propagating rays of a light sheet may directly correlate to an x row of an x-y grid of pixels of a projector, but may alternatively correspond to pixels along a diagonal or angled set of pixels of an x-y grid of pixels of the optical image generated by the projection system. For example, if height of the light sheet is constant across the volume, the path or traversal direction of an individual propagating ray of a light sheet may intersect a horizontal set of pixels in the x-y grid of the optical image generated by the projection system.

Alternatively, if the light sheet is generated with a compression lens or otherwise focused to achieve a decreasing height across the volume, or if the light sheet is generated with defocusing to achieve an increasing height across the volume, the path or traversal direction of an individual propagating ray of the light sheet may intersect a diagonal or angled set of pixels in the grid (e.g., x-y grid) of the optical image generated by the projection system. As used herein, a diagonal set of pixels refers to any set of pixels along a straight line that is at an angle to the coordinate axes of the grid (e.g., x-y grid) of the optical image generated by the projection system. A diagonal set of pixels may also be referred to herein as an angled set of pixels.

The modification of pixel brightness, or assignment of intensity levels, takes place along the direction of propagating rays of the light sheet and is cumulative. For example, in the case of a single light sheet and a photocurable medium that becomes more absorptive when projector pixels are turned “on”, the number of cumulative “on” pixels along the direction of a ray of light sheet is counted using software. This software then determines, based on the number of “on” pixels, the amount to dim the pixels closest to light sheet entry or light sheet exit in order to have them print at similar speed to pixels furthest from light sheet entry, which will be projected at higher relative intensity.

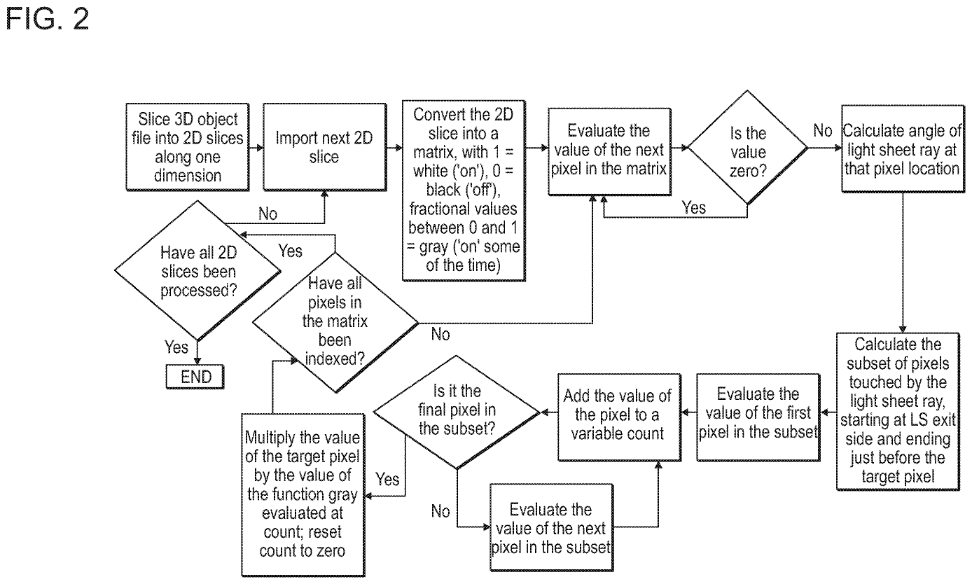

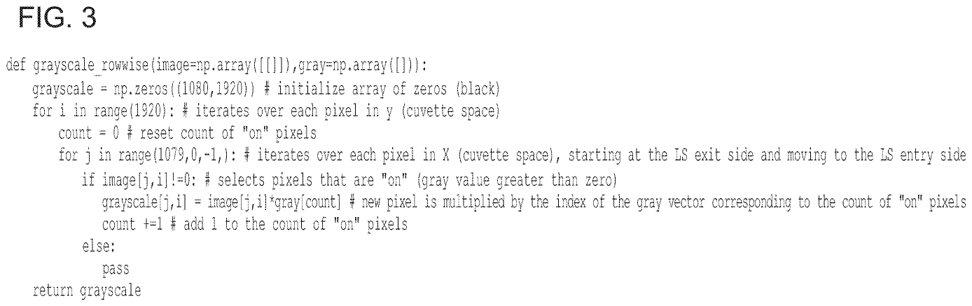

FIG. 2 provides a flow chart for an example of a preferred method in accordance with this aspect of the invention in which dimming of pixels is based on distance from light sheet exit. FIG. 3 provides an example of code for counting or cumulating the number of “on” pixels” of an optical image along the path of propagating light rays of a light sheet to which those pixels of the optical image are exposed and using this input to modify the gray values of the projected image. In the depicted code, the optical image is a 2D slice, the gray value of the projected optical image is a 1D vector of gray values, and the count is an integer variable.

Preferably gray is generalized to a continuous function of count, and count should be generalized to a floating point number to account for the counting of “partially on” gray pixels. The code shown in FIG. 3 is written in Python programming language. It can be desirable to run the code with Compute Unified Device Architecture (CUDA) (NVIDIA Corporation) or other accelerated or parallel computing platform. for accelerated processing.

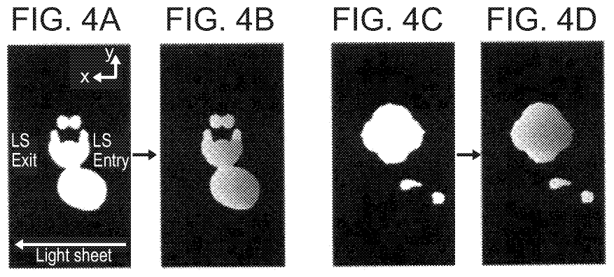

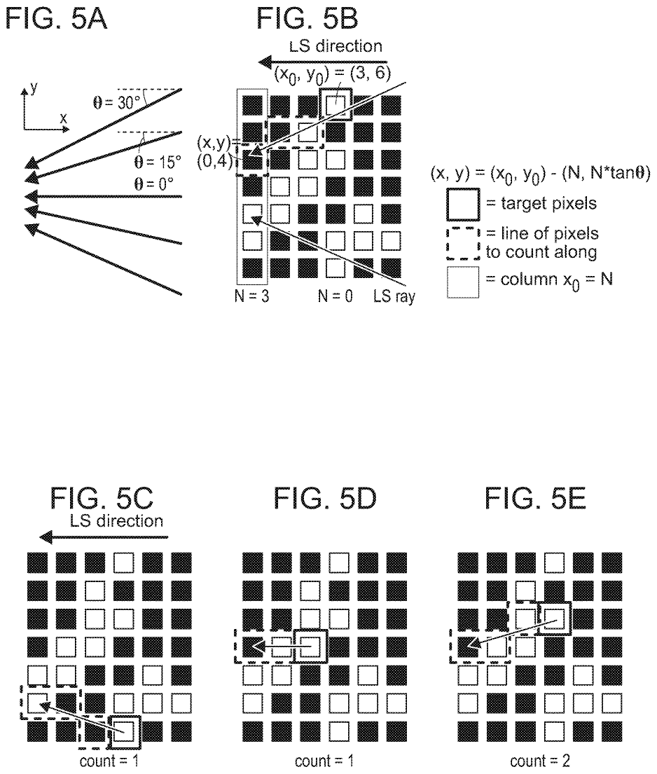

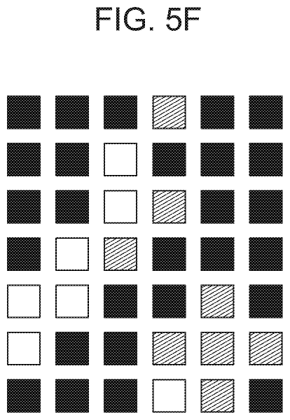

FIGS. 4A and 4C depict examples two-dimensional cross-sectional slices of an object before assignment of intensity levels in accordance with the present invention; and FIGS. 4B and 4D depict example two-dimensional cross-sectional slices of shown in FIGS. 4A and 4C, respectively, after assignment of intensity levels in accordance with the present invention to modify the pixel gray value based on cumulative “on” pixels in a row. In the depicted examples, the row corresponds to a horizontal row along the x-y grid of the projected optical image, but, as discussed above, this correspondence will not always be the case. This example assumes a system with no compression of the light sheet (θ=0). With compression or expansion of the light sheet to decrease or increase the height hereof as it traverses the volume, the algorithm demonstrated in FIGS. 5A-5F (below) is used.

FIGS. 5A-5F illustrate implementation of a row-wise grayscale algorithm, where a “row” corresponds to the path of a propagating ray of the light sheet, in a compressed light sheet system. FIG. 5A illustrates a simple compressed light sheet ray diagram, in which the angle of the rays relative to the x-direction, θ, varies based on both the x- and y-coordinates of the target pixel. FIG. 5B shows indexing through an arbitrary slice of black and white pixels by indexing N to find the coordinates (x, y) of each pixel whose value should contribute to count (dotted line) for the target pixel (solid line). The equation for finding this set of coordinates (x, y) is as follows: (x, y)=(x₀, y₀)−N*(1, tanθ), where (x₀, y₀) are the coordinates of the target pixel and N is the number of pixels away from the target pixel in the x-direction. In the case shown, (x, y)=(3, 6)−3*(1, tan(30°))=(0, 4.27)~(0, 4). When moving to a discretized regime, it is clear than an approximation needs to happen. As such, the y-coordinate 4.27 is rounded down to the nearest integer value of 4. This is only a first approximation as it only addresses one pixel per column. Preferably, the algorithm addresses a weighted average value of the two pixels adjacent to the light sheet ray. FIGS. 5C, 5D, and 5E show examples of how the count variable is calculated for different target pixels in an arbitrary slice. FIG. 5F shows an example of a completed scaled digital slice. (In the FIG. gray-scale is identified by hash-lines.) The value of count is used as an input for the gray function, as shown in FIG. 3, to determine the gray value to project for each pixel of a given count. This process is preferably done for each pixel in the slice. In addition to weighted average techniques, there are other well-known techniques in the computer graphics arts useful for interpolating pixel values. One of ordinary skill in the art can readily identify alternative techniques to interpolate pixel values (including, but not limited to, linear interpolation, trilinear interpolation, bilinear interpolation, or other methods of multivariate interpolation.

These cumulative modifications to light projected pixel brightness along a light sheet traversal direction can also be implemented in a case where a light sheet is generated by overlapping two sheets of light from opposite sides. In such a case, the brightness modifications are simply calculated twice, once for each intersection of projected image with each sheet, and then the resulting modifications are summed to provide the final modification for each slice.

The modifications to brightness or intensity levels based on cumulative “on” pixels can be modified to an otherwise discrete “on or off” projected image, but may also be applied on top of any pre-existing brightness corrections, commonly referred to as “grayscale” values, where an image is projected with values between a “fully on” or “fully off” pixel but rather with partially “on’ pixels. One example would be a system where a projected image is typically brighter on one side than the other. Implementing a cumulative grayscale modification would be implemented in addition to the already existing brightness gradient in the projected images. For example, can be done by multiplying the pixel values. For example, a value of 1 (white/“fully on”) multiplied by a value of 0.5 (gray/“half on”) will result in a new value of 0.5. However, a preexisting value of 0.75 (light gray/“75% on”) multiplied by a value of 0.5 will result in a new value of 0.375.

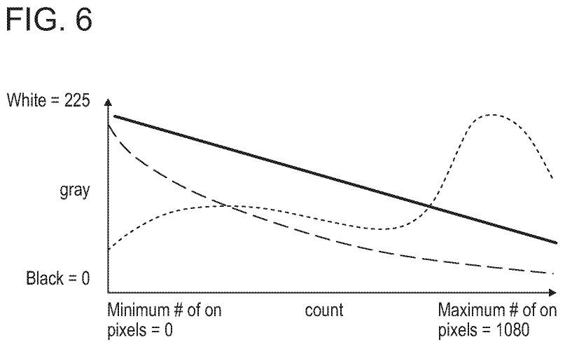

FIG. 6 illustrates how the variable gray is a continuous function of the “on” pixel count variable, count. Count is not necessarily an integer but could be a fraction if counting partially on (gray) pixels. The example code in FIG. 3 and the resultant slices shown in FIGS. 4A-4D assume the attenuation of light to be linear, such that the gray vector is also linear, as shown by the solid line. However, depending on the actual attenuation of the light sheet as a function of “on” pixels along a row, it may be determined that the dashed line curve show in FIG. 6 is more effective at compensating for light sheet attenuation and increasing cure homogeneity. Other dual wavelength photoinitiators could be determined to be well-suited to any arbitrary gray function, represented by the dotted line curve shown in FIG. 6. Importantly, gray=f(count).

A consequence of this algorithm is that changing pixel brightnesses or intensity levels will inherently alter the absorption along the light sheet ray. In theory, the algorithm should be applied recursively. Alternatively, the ideal algorithm can be determined empirically through experimentation.

It should be noted that these modifications preferably are performed slice by slice and row by row. As described above, a row is defined not as a row of an x-y grid along a projector pixel, but rather the one dimensional array of pixels that lay along the length of a ray of light sheet light, which may correspond to a row of pixels in a projector, but may also correspond to a diagonal or angled set of pixels along a projector pixel array.

It may also be preferred to take into account for the cumulative “on” pixel, row-wise modification proposed here, the brightness of each pixel along a row. For example, brighter pixels will have a larger (positive or negative) change in the light sheet attenuation, and therefore can be weighted to cause a larger modification to the projector image than dimmer pixels.

In some cases, for example projected images with many “on” pixels, and in a system where “on” pixels cause increased attenuation of light sheet light, dimming may be applied to pixels near the light sheet entry. While not wishing to be bound by theory, it is believed that modification of “on” pixel intensity levels in accordance with the present invention can cause the desired effect of homogenizing print speed across the slice, but may also cause the overall slice cure speed to be slower than other slices within the part that have fewer “on” pixels within rows. In such a case, it may be preferred to modify the exposure time applied to such a slice, for instance to increase exposure time, to achieve a similar total amount of photocuring as other slices in the volume with fewer “on” pixels. It may also be possible to project all slices for the same amount of exposure time and normalize all projected images to a single brightest pixel in the build volume, corresponding to the location where the light sheet is dimmest.

The systems and methods for the present invention may be useful with other 3D printing techniques that include initiation of a photochemical reaction in a photoreactive system via the absorption of dual wavelength light energy.

A method for producing a three-dimensional object in accordance with one aspect of the present invention includes:
a) providing a volume including a photohardenable composition comprising a photohardenable component and a dual wavelength photoinitiator;
b) exposing a selected location in the photohardenable composition to at least two excitation lights, the at least two excitation lights including a light sheet including a first excitation light comprising a first wavelength and an optical image including a second excitation light comprising a second wavelength, wherein the optical image comprises an arrangement including illuminated pixels and non-illuminated pixels, wherein each illuminated pixel in the arrangement has an intensity level that is scaled such that a cross-linking or polymerization reaction of the photohardenable composition resulting from exposure to the optical image and the light sheet at the selected location occurs at a rate that is substantially homogeneous; and
optionally c) repeating step b) one or more times wherein, for a repeated step, one or both of the selected location and optical image is the same as or different from a previous selected location and/or a previous optical image, and the intensity assigned to each illuminated pixel in the arrangement of a repeated step is assigned on a repeated step by repeated step basis.

In accordance with another aspect of the present invention, there is provided a method for producing a three-dimensional (3D) object with use of a 3D printer including at least two excitation lights including a first excitation light and a second excitation light, the method comprising:
a) providing a volume including a photohardenable composition comprising a photohardenable component and a dual wavelength photoinitiator wherein exposure of the photohardenable composition to a first excitation light including a first wavelength and a second excitation light including a second wavelength induces a crosslinking or polymerization reaction in the photohardenable composition;
b) generating a scaled model of two-dimensional cross-sectional digital slices of the 3D object to be printed, wherein each cross-sectional digital slice includes an arrangement including pixels to be illuminated and pixels not to be illuminated during printing of the slice, and wherein generating the scaled model of the digital slice comprises assigning an intensity level to each pixel to be illuminated with the second excitation light based on at least the position in the arrangement of each pixel to be illuminated with the second excitation light relative to one or more propagating rays of the first excitation light to which the pixel will be exposed during printing of the scaled digital slice;
c) exposing a selected two-dimensional cross-sectional plane in the volume of the photohardenable composition to at least a light sheet including the first excitation light comprising the first wavelength and an optical image including the second excitation light comprising second wavelength to form a cross-sectional slice of the 3D object, wherein the optical image comprises a two-dimensional cross-sectional slice of the 3D object generated from a scaled digital slice of the 3D object; and
optionally d) repeating step c) one or more times wherein, for a repeated step, one or both of the selected location and optical image is the same as or different from a previous selected location and/or a previous optical image.

Generating a scaled model of each two-dimensional cross-sectional digital slice can preferably further take into account the number of illuminated pixels in the path of the one or more propagating light rays of the first excitation light between the pixel and the end of the path traversed by the one or more propagating light rays traversed thereby in the arrangement.

In accordance with another aspect of the present invention, there is provided a method for producing a three-dimensional (3D) object with use of a 3D printer including at least two excitation lights including a first excitation light and a second excitation light, the method comprising:
a) obtaining a digital model corresponding to at least a portion of the 3D object;
b) slicing the digital model to generate a plurality of digital slices corresponding to sequential slices of the digital model for use in generating computer instructions for printing by the 3D printer, each slice including a two-dimensional cross-sectional slice of the 3D object (e.g., in an x-y plane), each slice including an arrangement including pixels to be illuminated and pixels not to be illuminated during printing of the slice;
c) generating a scaled model of each digital slice comprising assigning an intensity level to each pixel to be illuminated with the second excitation light based on at least the position in the arrangement of each pixel to be illuminated with the second excitation light relative to one or more propagating rays of the first excitation light to which the pixel will be exposed during printing of the scaled digital slice;
d) exposing a selected two-dimensional cross-sectional plane in a volume of a photohardenable composition including a dual-wavelength photoinitiator to at least a light sheet including the first excitation light comprising a first wavelength and an optical image including the second excitation light comprising a second wavelength to form a cross-sectional slice of the 3D object, wherein the optical image comprises a two-dimensional cross-sectional slice of the 3D object generated from a scaled digital slice of the 3D object; and
optionally e) repeating step d) one or more times wherein, for a repeated step, one or both of the selected location and optical image is the same as or different from a previous selected location and/or a previous optical image.

Generating a scaled model of each two-dimensional cross-sectional digital slice can preferably further take into account the number of illuminated pixels in the path of the one or more propagating light rays of the first excitation light between the pixel and the end of the path traversed by the one or more propagating light rays in the arrangement.

In accordance with another aspect of the present invention, there is provided a method for producing a three-dimensional (3D) object with use of a 3D printer including at least two excitation lights including a first excitation light and a second excitation light, the method comprising:
a) providing a volume including a photohardenable composition comprising a photohardenable component and a dual wavelength photoinitiator;
b) slicing a digital model corresponding to at least a portion of the 3D object into a plurality of two-dimensional sequential slices of the digital model of the 3D object (e.g., in an x-y plane), each digital slice including an arrangement including pixels to be illuminated by the second excitation light during printing of a slice and pixels not to be illuminated by the second excitation light during printing of the slice;
c) generating a scaled model of each digital slice wherein each pixel in a digital slice to be illuminated with the second excitation is assigned an intensity level based on at least its position in the arrangement relative to one or more propagating rays of the first excitation light to which the pixel will be exposed during printing of the scaled digital slice;
d) exposing a selected two-dimensional cross-sectional plane in the volume of the photohardenable composition to at least a light sheet including a first excitation light comprising a first wavelength and an optical image including a second excitation light comprising a second wavelength to form a cross-sectional slice of the 3D object, wherein the optical image comprises the scaled digital slice corresponding to the selected two-dimensional cross-sectional slice of the 3D object generated from the scaled model of the 3D object; and
optionally e) repeating step d) one or more times wherein, for a repeated step one or both of the two-dimensional cross-sectional plane in the volume and the optical image is the same as or different from a previous selected two-dimensional cross-sectional plane in the volume and/or a previous optical image.

Generating a scaled model of each two-dimensional cross-sectional digital slice can preferably further take into account the number of illuminated pixels in the path of the one or more propagating light rays of the first excitation light between the pixel and the end of the path traversed by the one or more propagating light rays in the arrangement.

The light sheet and individual optical projections are preferably selectively directed into the volume of photopolymerizable liquid to print or form the desired three-dimensional object.

In methods for producing a 3D object described herein the optical image that is projected to the selected location can include a grid of pixels. As described above, the optical image can comprise a digital slide or scaled digital slice of the object to be printed.

Preferably a method for producing a 3D object described herein achieves a rate of cross-linking or polymerization reaction of the photohardenable composition resulting from exposure to optical image and light sheet at the selected location that is substantially homogeneous.

Optionally, a method for producing a 3D object described herein can further include a second light sheet including the first excitation light including the first wavelength, wherein the second light sheet is directed into the volume to overlap the other light sheet, and wherein the intensity levels of illuminated pixels included in the optical image is based on the position in the arrangement of each given illuminated pixel relative to propagating light rays included in each of the two light sheets to which each of the given illuminated pixels is exposed during printing of the scaled digital slice.

The present methods are particularly advantageous for use with a photohardenable composition including a dual wavelength photoinitiator that demonstrates an increase or decrease in absorbance by the photohardenable composition of the first wavelength when exposed to both the first wavelength and second wavelength.

In method described herein, in assigning an intensity level to a pixel, a row of the grid of pixels in the grid corresponds to a path traversed by one or more propagating light rays of the first excitation light from a first side edge of the optical image to a second side edge of the optical image to which the pixel is exposed, wherein the first and second side edges of the optical image are opposite one another.

In cases in which absorbance of the first wavelength by the photoinitiator is increased in the presence of the second wavelength, it can be desirable to assign a maximum intensity level to one or more positions included at the second edge of the optical image that are farthest from the first edge of the arrangement with each given pixel illuminated with the second excitation light that is located along the path of the one or more propagating rays of the first excitation light to which the each given pixel along the path is exposed being assigned an intensity level that decreases as the position of the each given illuminated pixel is progressively closer to the first edge taking into account the number of illuminated pixels along the path between the second edge and the given pixel.

In cases in which absorbance of the first wavelength by the photoinitiator is decreased in the presence of the second wavelength, it can be desirable to assign a maximum intensity level to one or more positions included at the first edge of the optical image (e.g., the edge of the optical image that is closest to the side of the container from which the light sheet enters the container) with each given pixel illuminated with the second excitation light that is located along the path of the one or more propagating rays of the first excitation light to which the each given pixel along the path is exposed being assigned an intensity level that decreases as the position of the each given illuminated pixel is progressively farther away from the first edge taking into account the number of illuminated pixels along the path between the first edge and the given pixel.

Alternatively, an algorithm can assign a minimum intensity level to one or more illuminated pixel locations included in the first edge of the optical image that are closest to side of the image first traversed by propagating light rays of the light sheet, the minimum intensity level being below which the degree of polymerization will be unsatisfactory for a given application. In this case, the algorithm can be provided with a constant representing this minimum, such as I_min, and then modify the values of the light sheet ray path in a manner that forbids going below I_min. In one approach, the algorithm can crawl along the propagation direction of the light sheet, assigning a value of I_min or greater to the first “on” pixel it encounters, and providing incrementally higher values to subsequent “on” pixels it encounters. Preferably none of the final scaled intensity levels or values for an illuminated pixel are greater than the optical system of the printer can deliver, or that it be set to a maximum value,

Propagating rays of a light sheet that traverse the optical image can follow a path that is horizontal or diagonal. The path is largely dependent upon the height of the light sheet as it passes through the volume.

For example, for a light sheet generated with use of a compression lens, the height of the light sheet decreases from where it enters the volume to the opposite side of the volume where it exits the volume. In such case, the path of a given propagating light ray included in a light sheet created with a lens to decrease light sheet height is based on (i) its position in the light sheet, (ii) the size and focal length of the compression lens, and (iii) the position of the lens relative to the optical image. The path of the propagating rays in such case will typically follow a linear path along a diagonal of the projector pixel grid.

In an example of a light sheet generated in an expanding fashion, the height of the light sheet can increase from where it enters the volume as it passes through the volume. In such case, the path of the propagating rays also follow a linear path along a diagonal of the projector pixel grid.

In other examples in which the height of the light sheet is substantially unchanged as it passes through the volume, the path of the light sheet propagating rays through the volume is linear along a horizontal row of the projector pixel grid.

In accordance with another aspect of the present invention there is provided a method for improving cure rate homogeneity across a light sheet traversal direction through a photohardenable composition, the method comprising:
a) obtaining a digital model corresponding to at least a portion of a 3D object;
b) slicing the digital model to generate a plurality of digital slices corresponding to the digital model for use in generating computer instructions for printing by a 3D printer, each slice including a two-dimensional cross-sectional slice of the 3D object (e.g., in an x-y plane), each slice including an arrangement including pixels to be illuminated and pixels not to be illuminated during printing of the slice;
c) generating a scaled model of each digital slice comprising assigning an intensity level to each pixel to be illuminated with the second excitation light based on at least the position in the arrangement of each pixel to be illuminated with the second excitation light relative to one or more propagating rays of the first excitation light to which the pixel will be exposed during printing of the scaled digital slice;
d) exposing a selected two-dimensional cross-sectional plane in a volume of the photohardenable composition, wherein the photohardenable composition includes a dual-wavelength photoinitiator, to at least a light sheet including a first excitation light comprising a first wavelength and an optical image including a second excitation light comprising a second wavelength to form a cross-sectional slice of the 3D object, wherein the optical image comprises a two-dimensional cross-sectional slice of the 3D object generated from a scaled digital slice of the 3D object; and
optionally e) repeating step d) one or more times wherein, for a repeated step, one or both of the selected location and optical image is the same as or different from a previous selected location and/or a previous optical image.
wherein the cure rate across a light sheet traversal direction through the photohardenable composition of the cross-sectional slices of the 3D object being printed is more homogeneous than printing without use of the scaled digital slices.

Preferably the cure rate is substantially homogeneous across the light sheet traversal direction through the photohardenable composition of one or more cross-sectional slices of the 3D object.

In accordance with another aspect of the present invention there is provided a method for improving cure rate homogeneity across a light sheet traversal direction through a photohardenable composition, the method comprising:
a) providing a volume including the photohardenable composition, wherein the photohardenable composition includes a dual wavelength photoinitiator;
b) slicing a digital model corresponding to at least a portion of a 3D object into a plurality of two-dimensional sequential slices of the digital model of the 3D object (e.g., in an x-y plane), each digital slice including an arrangement including pixels to be illuminated by the second excitation light during printing of a slice and pixels not to be illuminated by the second excitation light during printing of the slice;
c) generating a scaled model of each digital slice wherein each pixel in a digital slice to be illuminated with the second excitation is assigned an intensity level based on at least its position in the arrangement relative to one or more propagating rays of the first excitation light to which the pixel will be exposed during printing of the scaled digital slice;
d) exposing a selected two-dimensional cross-sectional plane in the volume of the photohardenable composition to at least a light sheet including a first excitation light comprising a first wavelength and an optical image including a second excitation light comprising a second wavelength to form a cross-sectional slice of the 3D object, wherein the optical image comprises the scaled digital slice corresponding to the selected two-dimensional cross-sectional slice of the 3D object generated from the scaled model of the 3D object; and
optionally e) repeating step c) one or more times wherein, for a repeated step one or both of the two-dimensional cross-sectional plane in the volume and the optical image is the same as or different from a previous selected two-dimensional cross-sectional plane in the volume and/or a previous optical image,
wherein the cure rate across a light sheet traversal direction through the photohardenable composition of the cross-sectional slices of the 3D object being printed is more homogeneous than printing without use of the scaled digital slices.

Preferably the cure rate is substantially homogeneous across the light sheet traversal direction through the photohardenable composition of one or more cross-sectional slices of the 3D object.

In the methods described herein, the scaling of the light intensity levels of the pixels and assignment of the scale intensity levels to the pixels of the optical image to be illuminated is carried out with use of a computer processor.

In accordance with another aspect of the present invention there is provided a system comprising:
a container capable of holding a volume of a photohardenable composition, wherein the container is adapted for passage of excitation light into the container;
two optical systems including a first optical system for generating and projecting a light sheet for generating and directing a light sheet comprising a first excitation light including a first wavelength to a selected location in the container and a second optical system for generating and projecting an optical image comprising an arrangement including illuminated pixels including a second excitation light including a second wavelength and non-illuminated pixels to a selected location in the photohardenable composition preferably such that the optical image and light sheet overlap in a common plane at the selected location; and
a controller to control the printing of a 3D object, wherein the controller is configured to perform operations comprising:
generating a scaled model of optical images corresponding to two-dimensional cross-sectional digital slices of the 3D object comprising assigning an intensity level to each pixel to be illuminated with the second excitation light including the second wavelength based on at least the position in the arrangement of each pixel to be illuminated with the second excitation light relative to one or more propagating rays of the first excitation light to which the pixel will be exposed during printing of the scaled digital slice; and
controlling the optical system for directing the optical image to the selected location in the photohardenable composition based on the scaled digital slice information and directing the light sheet to the selected location in the photohardenable composition.

Generating a scaled model of each two-dimensional cross-sectional digital slice can preferably further take into account the number of illuminated pixels in the path of the one or more propagating light rays of the first excitation light between the pixel and the end of the path traversed by the one or more propagating light rays in the arrangement.

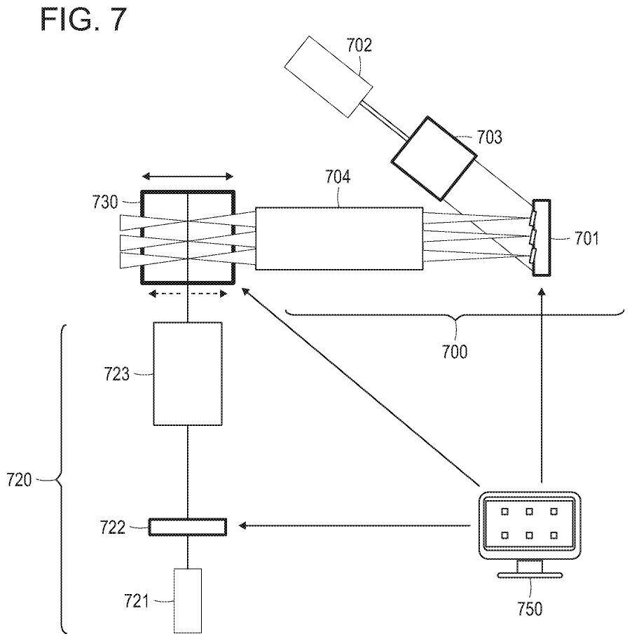

FIG. 7 illustrates a schematic of system for use in the methods and systems described herein.

In the example of the depicted figure, the system includes a light sheet generating system 720 and optical projection system 700 positioned such that the light sheet generating system generates and directs a light sheet to a selected location in a volume of a photohardenable composition included in a container 730 and the optical projection system generates and projects a scaled digital slice of an optical image to the selected location in the volume at which the light sheet and scaled digital slice of the optical image intersect or overlap and include a polymerization or cross-linking reaction for at least partially forming a two dimensional cross-sectional slice of the object to be printed. The container can optionally be positioned on a translation stage for translating the position of the container in the system during printing. The optical projection system 700 includes a projection device (e.g., a SLM (such as, by way of non-limiting example, a DMD) 701 and a light source 702 in combination with illumination optics 703 to illuminate the projection device. Such illumination optics can optionally comprise beam conditioning and condenser optics and relay optics. A light source for a second excitation light including a second wavelength illuminates the projection device. A light source comprising a non-pulsed laser or a continuous wave laser can be preferred. In the depicted example, projection optics 704 are positioned between the projection device and a container 730. Projection optics can be used for magnifying and projecting a focused an optical projection of excitation light comprising a two-dimensional image into the container. Optionally, prism(s) (not shown) can be positioned between the projection device 701 and the projection optics 704. In the depicted example, an optical image (typically a 2-dimenstional cross-section slice of the object to be printed) is projected to the selected focal plane at the selected location in the volume. The optical image is orthogonal to the direction in which it is projected into the volume.

The example of the depicted light sheet generating system 720 includes a light source of a first excitation light including a first wavelength, preferably a laser, from which a light sheet is generated by a light sheet generator 722. The light sheet generating system 720 can also preferably include further light sheet optics 723 between the light sheet generator and the container.

Preferably the directions in which the light sheet and optical image are directed to the selected location in the volume are orthogonal to each other with the optical image and light sheet intersecting or overlapping in a coplanar manner.

A computer 750 is also shown. The computer 750 can include a processor, memory, and interfaces such as a network interface or a Universal Serial Bus (USB) interface. The processor can be one or multiple processors, which can each include multiple processor cores. The memory can include volatile memory such as Random Access Memory (RAM). The memory can include non-volatile memory such as flash memory or read-only memory (ROM). The computer can include one or more types of computer storage media and devices, which can include the memory to store instructions of programs that run on the processor. For example, a 3D printing program can be stored in the memory and run on the processor to implement the techniques described herein. In some implementations, the controller can include the 3D printing program.

The 3D printing program can include a slicing program for transforming a digital model into a sequence of layers that collectively form the structure when projected onto the photohardenable composition on the selected timescale and at the selected speed. The slicing program can access a file containing mesh or another kind of 3D part data that represents a digital model. The slicing program can map the digital model to a discrete array of pixels. In some implementations, for example, the digital model can be sliced into grids of pixels.

The 3D printing program, the controller, or both can implement methods of the invention including assignment of intensity levels to pixels in the optical image using a scaled digital slide based on at least its position in the arrangement relative to one or more propagating rays of the first excitation light to which the pixel will be exposed during printing of the scaled digital slice. The light intensity levels can range from 100% (e.g., for any “on” pixel assigned maximum brightness to zero for an “off” (or non-illuminated) pixel, and multiple brightness levels therebetween corresponding to the assigned intensity level. Based on the assigned intensity levels, the 3D printing program, the controller, or both can output layer information, such as graphic files or light modulation command sequences, that represent respective patterns of light to be generated for each scaled digital slice of the object to be printed.

Software can be used to coordinate generation of the scaled digital slices from the projector device, preferably a spatial light modulator, so that the part is developed plane by plane along the dimension with respect to which the 3D object file is sliced. Selection of computer controls and software is within the skill of the person of ordinary skill in the relevant art.

There are a variety of optical modulators that can provide patterned light of controllable intensity. For example, a ray from a laser can be scanned or steered to create patterns on a surface, and the laser's intensity can be varied during the spot's movement. There are also two-dimensional spatial light modulators (SLMs) which can impart two-dimensional patterns on light. These include liquid crystal modulators that are capable of a variety of modulation ratios between “on” and “off” as well as binary SLMs such as micromirror arrays that principally have only two states: on and off. In the latter case, a variable intensity can be effectively achieved in several ways. In one way, the binary SLM can use in-plane dithering, such as Floyd-Steinberg dithering, to achieve a range of intensities when considered in a locally-averaged basis. Another way for binary SLMs to provide a range of intensities is through flickering, in which the ratio of on-to-off states of a pixel over a time-averaging window provides an approximation to a desired intensity.

As mentioned above, he optical projection system can comprise a DMD. Other spatial light modulator (e.g., an LCOS, LCD, or μLED) can alternatively be included in a projection system).

The example of the system depicted in FIG. 7 includes a light sheet generating system 720 for generating a plane of light or light sheet and directing the light sheet to a selected location in the volume. The major face of the plane of light or light sheet is preferably orthogonal or substantially orthogonal the projection axis of the optical image such that the light sheet and optical image intersect or overlap in a plane at the selected location in the volume. The light sheet generating system includes a light source 721 which directs through an optical arrangement (that can include, for example, a light sheet generator 722 and light sheet optics 723) for generating and directing a light sheet into the container 630.

An example of a light sheet generating system can include a light source 721 which directs collimated light through an optical arrangement for generating the light sheet can include a light sheet generator 722 that can include a Powell lens (not shown), and light sheet optics 723 including, for example, one or more cylindrical lens, for directing the light sheet into the container 730. An example of a collimated light source is a free space non-pulsed laser. Light sheet optics including other different numbers and/or types of lenses may also be determined by the skilled artisan to be suitable. The use of cylinder lenses can be preferred as this permits independent shaping of the light distribution in orthogonal directions. Examples of cylindrical lenses include off the shelf plano convex cylindrical lenses with focal lengths in the range 25 mm-250 mm, available from Thorlabs.

Optionally, a galvanometer, polygon scanner, MEMS scanner, diffractive optical elements, cylindrical lenses, or axicon lenses, with or without additional optical components, can be included in place of the Powell lens.

Other systems and configurations for generating and directing a light sheet to a selected location in the volume can be used.

Light sources included in the system are preferably selected taking into consideration the photohardenable liquid being used and the hardening mechanism therefor. Such considerations include the wavelength(s) preferred for the particular photohardening mechanism and power levels preferred therefor. Selection of suitable light sources is within the skill of the person of ordinary skill in the relevant art.

As discussed above, a light sheet system can optionally include compression for decreasing the height of the light sheet as it passes through the volume or defocusing for increasing the height of the light sheet as it passes through the volume.

As also mentioned above, a system can optionally be configured to generate and direct light sheets into the volume from opposite sides of the volume to overlap with each other in the volume and further intersect or overlap with the optical image.

While the figures depict examples of systems including a container, optionally the container can be included as a component of a system or separately provided for inclusion prior to use.

Optionally any light source can be included as component of a light sheet generating system or optical image projection system or can be separately supplied for use therewith.

The methods described herein can provide improved cure rate homogeneity across the light sheet traversal direction through the photohardenable composition compared when a scaled digital slice is not included.

Preferably each illuminated pixel in the arrangement of illuminated pixels in a scaled digital slice has an intensity level that is scaled such that the rate of a cross-linking or polymerization reaction of the photohardenable composition resulting from exposure to optical image and light sheet at the selected location is substantially homogeneous.

In accordance with another aspect of the present invention there is provided a method for generating a scaled digital model for printing a three-dimensional (3D) object with at least a first excitation light including a first wavelength and a second excitation light including a second wavelength, the method comprising:

generating a scaled digital model of two-dimensional cross-sectional digital slices of the 3D object comprising assigning an intensity level to each pixel to be illuminated with the second excitation light, wherein a digital slice includes an arrangement including pixels to be illuminated by the second excitation light during printing of a slice and pixels not to be illuminated by the second excitation light during printing of the slice, and wherein the assignment of the intensity level is based on at least the position of the pixel to be illuminated in the arrangement relative to one or more propagating rays of the first excitation light to which the pixel will be exposed during printing of the scaled digital slice and taking into account the number of illuminated pixels in a path of the one or more propagating light rays of the first excitation light between the pixel and the end of the path traversed by the one or more propagating light rays in the arrangement.

In accordance with another aspect of the present invention there is provided a method for generating a scaled digital model for printing a three-dimensional (3D) object with at least a first excitation light including a first wavelength and a second excitation light including a second wavelength, the method comprising:
a) obtaining a digital model corresponding to at least a portion of the 3D object;
b) slicing the digital model to generate a plurality of digital slices corresponding to the digital model for use in generating computer instructions for printing by a 3D printer, each slice including a two-dimensional cross-sectional slice of the 3d object (e.g., in an x-y plane), each slice including an arrangement including pixels to be illuminated during printing of the slice and pixels not to be illuminated by the second excitation light during printing of the slice;
c) generating a scaled digital model of each digital slice comprising assigning an intensity level to each pixel in a digital slice to be illuminated with the second excitation light during printing to provide a scaled digital model of each two-dimensional cross-sectional slice of the 3D object to be printed, wherein the assignment of the intensity level is based on at least the position in the arrangement of each pixel to be illuminated with the second excitation light relative to one or more propagating light rays of the first excitation light to which the pixel will be exposed during printing of the scaled digital slice.

Generating a scaled model of each two-dimensional cross-sectional digital slice can preferably further take into account the number of illuminated pixels in the path of the one or more propagating light rays of the first excitation light between the pixel and the end of the path traversed by the one or more propagating light rays in the arrangement.

A digital slice and scaled digital slice can include a grid of pixels. Preferably, in assigning an intensity level to a pixel, a row of the grid of pixels comprises a line of individual pixels along a path of one or more propagating light rays of the first excitation from a first side edge of the arrangement to an opposite second side edge of the arrangement to which pixels illuminated with the second excitation light will be exposed during printing of the scaled digital slice, and a second factor in generating the scaled digital model of each slice is also based on the number of pixels illuminated with the second excitation light in the row. The intensity levels of the illuminated pixels in a given row are preferably assigned independently from the assignment of the intensity levels to illuminated pixels in a different row.

The first excitation light can be included in a configuration that includes one or more propagating light rays that traverse digital slice in a direction from a first side edge of the pixel arrangement to an opposite second side edge of the pixel arrangement.

In accordance with another aspect of the present invention there is provided a method for generating a scaled digital model for printing a three-dimensional (3D) object with at least a first excitation light including a first wavelength and a second excitation light including a second wavelength, the method comprising:
a) obtaining a digital model corresponding to at least a portion of the 3D object and slicing the digital model into a plurality of two-dimensional slices of the digital model of the 3D object (e.g., in an x-y plane), each slice including an arrangement including pixels to be illuminated by the second excitation light and pixels not to be illuminated by the second excitation light during printing of the scaled digital slice; and
b) generating a scaled digital model of each digital slice comprising assigning an intensity level to each pixel of a digital slice to be illuminated with the second excitation light based on at least its position in the arrangement relative to one or more propagating rays of the first excitation light to which the pixel will be exposed during printing of the scaled digital slice and taking into account the number of illuminated pixels in the path of the one or more propagating light rays of the first excitation light between the pixel and the end of the path traversed by the one or more propagating light rays in the arrangement.

Optionally, one or more additional operations can be applied to a projected two-dimensional (2D) slice comprising an optical image, before or after other image processing operations, wherein the perimeter of the optical image is assigned a brighter pixel intensity relative to non-perimeter regions of the image. For example, at some point after calculating the grayscale gradient for the scaled digital image to be used, a blurring function may be applied to the resulting images to reduce sharp edges in parts resulting from dramatic changes in light intensity between adjacent pixels.

As mentioned above, a digital slice and a scaled digital slice can include a grid of pixels. Preferably, in assigning an intensity level to a pixel, a row of the grid of pixels comprises a line of individual pixels along a path of one or more propagating light rays of the first excitation from a first side edge of the arrangement to an opposite second side edge of the arrangement to which pixels illuminated with the second excitation light will be exposed during printing of the scaled digital slice, and a second factor in generating the scaled digital model of each slice is also based on the number of pixels illuminated with the second excitation light in the row. The intensity levels of the illuminated pixels in a given row are preferably assigned independently from the assignment of the intensity levels to illuminated pixels in a different row.

The one or more pixels to be illuminated by the second excitation light that are located at one or more positions included in the second edge of the arrangement that are farthest from the first edge of the arrangement are preferably assigned a maximum intensity level with each given pixel to be illuminated with the second excitation light that is located along the path of the one or more propagating light rays of the first excitation light is assigned an intensity level that decreases as the position of the given pixel is progressively closer to the first edge taking into account the number of illuminated pixels between the second edge and the given pixel.

In the methods described herein, the scaling of the light intensity levels of the pixels and assignment of the scale intensity levels to the pixels of the optical image to be illuminated is carried out with use of a computer processor.

The methods for generating a scaled digital model for printing a three-dimensional (3D) object described herein are particularly advantageous for use with a photohardenable composition that demonstrates an increase or decrease in absorbance by the photohardenable composition of the first wavelength when exposed to both the first wavelength and second wavelength.

In cases in which absorbance of the first wavelength by the photoinitiator is increased in the presence of the second wavelength, it can be desirable to assign a maximum intensity level to one or more positions included at the second edge of the optical image that are farthest from the first edge of the arrangement with each given pixel illuminated with the second excitation light that is located along the path of the one or more propagating rays of the first excitation light to which the each given pixel along the path is exposed being assigned an intensity level that decreases as the position of the each given illuminated pixel is progressively closer to the first edge taking into account the number of illuminated pixels along the path between the second edge and the given pixel.

In cases in which absorbance of the first wavelength by the photoinitiator is decreased in the presence of the second wavelength, it can be desirable to assign a maximum intensity level to one or more positions included at the first edge of the optical image (e.g., the edge of the optical image that is closest to the side of the container from which the light sheet enters the container) with each given pixel illuminated with the second excitation light that is located along the path of the one or more propagating rays of the first excitation light to which the each given pixel along the path is exposed being assigned an intensity level that decreases as the position of the each given illuminated pixel is progressively farther away from the first edge taking into account the number of illuminated pixels along the path between the first edge and the given pixel.

Propagating rays of a light sheet that traverse the optical image can follow a path that is horizontal or diagonal. The path is largely dependent upon the height of the light sheet as it passes through the volume.

For example, for a light sheet generated with use of a compression lens, the height of the light sheet decreases from where it enters the volume to the opposite side of the volume where it exits the volume. In such case, the path of a given propagating light ray included in a light sheet created with a lens to decrease light sheet height is based on (i) its position in the light sheet, (ii) the size and focal length of the compression lens, and (iii) the position of the lens relative to the optical image. The path of the propagating rays in such case will typically follow a linear path along a diagonal of the projector pixel grid.

In an example of an expanding light sheet, the height of the light sheet can increase from where it enters the volume as it passes through the volume. In such case, the path of the propagating rays also follow a linear path along a diagonal of the projector pixel grid.

In other examples in which the height of the light sheet is substantially unchanged as it passes through the volume, the path of the light sheet propagating rays through the volume is linear along a horizontal row of the projector pixel grid.

In the methods described herein, the scaling of the light intensity levels of the pixels and assignment of the scale intensity levels to the pixels of the optical image to be illuminated is carried out with use of a computer processor.

Preferably in methods in accordance with one or more aspects of the present invention, a scaled digital slice can be further modified to take into account intensity levels of gray-scale pixels included in the arrangement.

Preferably in method in accordance with one or more aspects of the present invention, the intensity levels of the illuminated pixels in a given row are assigned independently from the assignment of the intensity levels to illuminated pixels in a different row.

Methods for producing a three-dimensional object described herein, methods for generating a scaled digital model for printing a three-dimensional (3D) object, and systems described herein are advantageous for use with photohardenable compositions comprising a dual wavelength photoinitiator comprising a photochromic molecules which photochromic molecules can more preferably include one or more functional groups attached thereto.

Methods for producing a three-dimensional object, methods for generating a scaled digital model for printing a three-dimensional (3D) object, and systems described herein can be particularly advantageous for use in methods of 3D printing objects that including a photohardenable composition comprising a dual wavelength photoinitiator comprising a substituted or unsubstituted P-type photochromic molecule. Examples of dual wavelength photoinitiators comprising a substituted or unsubstituted P-type photochromic molecule that can be preferred include substituted or unsubstituted diarylethene molecules.

Dual wavelength photoinitiators for inclusion in a photohardenable composition for use in the present invention preferably possess photochromic properties and can be converted to a second form (or activated form) upon irradiation with light of a first wavelength, which second form can be converted back to the first form upon irradiation with light of a second wavelength, process of cycling between these forms capable of inducing a crosslinking or polymerization reaction in the photohardenable resin component. The conversion of the photoswitchable photoinitiators described herein to a second form (or activated form) of the molecule (e.g., an isomer thereof) is preferably a reversible photochemical structural change. (Dual wavelength photoinitiators including such photochromic properties are also referred to herein as “photoswitchable photoinitiators”.)

Several considerations in selecting a particular photoswitchable photoinitiator for inclusion in a photohardenable composition or method in accordance with the present invention include, by way of example, but not limited to, the absorption spectra and Δₘₐₓ of the molecule and its second forms, the solubility of the photoswitchable photoinitiator in the photohardenable resin component, the photosensitivity of the second form of the photoswitchable photoinitiator, the amount of initial concentration of the second form in the monomer solution, the stability of the photoswitchable photoinitiator and the reduction and oxidation potentials of the second form of the photoswitchable photoinitiator.

Non-limiting examples of photochromic molecules included in a dual-wavelength photoinitiator including a substituted or unsubstituted photochromic molecule include, but are not limited to, photochromic molecules, (e.g., but not limited to, a benzospiropyran molecule, a naphthopyran molecule, a spironaphthoxazine molecule, a diarylethene molecule) which photochromic molecules can more preferably include one or more functional groups attached thereto. Such photochromic molecules can undergo a reversible intramolecular transformation forming an active form of the molecule by irradiation (photochromic). Such preferred photoswitchable photoinitiators, e.g., in the case of benzospiropyrans, naphthopyrans, and spironaphthoxazines, can function by light activated opening of the photoswitchable photoinitiator to form the activated form upon exposure to a first wavelength. In the case of diarylethenes, the activation process instead involves a ring-closing. The active form may subsequently absorb light of a different second wavelength to form an excited state of the active form which may subsequently induce photoinitiation, either alone or in combination with a coinitiator (e.g., amine, thiol, organoborate compounds, onium salts).

Preferred photohardenable compositions including a photoswitchable photoinitiator are particularly suitable for use in the methods of the present invention for forming three-dimensional objects. The photoswitchable photoinitiator molecule in its initial form and the photoinitiator molecule in its activated second form can have sufficiently distinct absorption spectra that once the initial form of the molecule is activated form, the activated form absorbs in a wavelength region where the initial form is substantially non-absorbing. In this way, the activated form can be independently excited with the second wavelength without causing unintended excitation of the initial form by the second wavelength. The second wavelength can excite the activated form to generate free radicals or otherwise induce desired hardening of the photohardenable resin component once the activated form has been generated by exposure to the first wavelength.

Examples of photoswitchable photoinitiators suitable for inclusion in the photohardenable composition in accordance with the present invention are described in International Application No. PCT/US2022/037491, filed Jul. 18, 2022, of Quadratic 3D, Inc., U.S. Provisional Application No. 63/440,085 of Quadratic 3D, Inc., filed Jan. 19, 2023, U.S. Provisional Application No. 63/450,931 of Quadratic 3D, Inc., filed Mar. 8, 2023, International Application No. PCT/US2023/022172 of Quadratic 3D, Inc. filed May 13, 2023, U.S. Provisional Patent Application No. 63/450,936 of Quadratic 3D, Inc. filed on Mar. 8, 2023, International Application No. PCT/US2023/022173 of Quadratic 3D, Inc. filed May 13, 2023International Application No. PCT/US2022/042179, filed Aug. 31, 2022, of Quadratic 3D, Inc., International Application No. PCT/US2022/042183, filed Aug. 31, 2022, of Quadratic 3D, Inc., International Application No. PCT/US2022/042186, filed Aug. 31, 2022, of Quadratic 3D, Inc., each of the foregoing applications being hereby incorporated herein by reference in its entirety.

Other information that may be useful in connection with the various aspects of the present inventions includes International Application No. PCT/US2022/052157, filed Dec. 7, 2022, of Quadratic 3D, Inc., and International Application No. PCT/US2022/039766, filed Aug. 9, 2022, of Quadratic 3D, Inc., and International Application No. PCT/US2023/022171, filed May 13, 2023, of Quadratic 3D, Inc., each of the foregoing applications being hereby incorporated herein by reference in its entirety.

Additional examples of photoswitchable photoinitiators suitable for inclusion in the photohardenable composition in accordance with the present invention include photoswitchable photoinitiators comprising a first unit comprising a photochromic molecule comprising one or more rings of atoms wherein one or more of the rings of atoms includes one or more substituents, and a second unit comprising a polycyclic group including at least two fused rings of atoms, wherein at least one of the fused rings of atoms includes a carbon atom with a substituent comprising a double bonded oxygen, wherein the second unit is attached to the first unit, and wherein the first unit and the second unit lack a ring member that is common to both units, as described in U.S. Provisional Patent Application No. 63/341,594, filed May 13, 2022, of Quadratic 3D, Inc. and International Application No. PCT/US2023/022170 of Quadratic 3D, Inc. filed May 13, 2023, which is hereby incorporated herein by reference in its entirety. A photoswitchable photoinitiator described therein, represented by Formula II-7 is an example of a photoswitchable photoinitiator that can be preferred. (Such photoswitchable photoinitiator is also referred to herein as 2,2′-((6-methoxy-4-phenyl-2H-benzo[h]chromene-2,2-diyl)bis(4,1-phenylene))bis(9H-thioxanthen-9-one).)

Examples of preferred dual wavelength photoinitiators for use in the methods of the present invention include substituted or unsubstituted P-type photochromic molecules. Examples of such preferred photoinitiators include, but are not limited to, substituted or unsubstituted diarylethene molecules. See, for example, International Application No. PCT/US2023/022172 of Quadratic 3D, Inc. filed May 13, 2023.

A photohardenable resin component suitable for inclusion in a photohardenable composition can comprise any resin (e.g., a monomer, an oligomer, a pre-polymer, a polymer, or a mixture including at least one the foregoing) that is photohardenable by exposure to light in the presence of a photoinitiator. Examples of photohardenable resin components useful for inclusion in a photohardenable composition include ethylenically unsaturated compounds and, more specifically, a polyethylenically unsaturated compounds. These compounds include both monomers having one or more ethylenically unsaturated groups, such as vinyl or allyl groups, and polymers having terminal or pendant ethylenic unsaturation. Such compounds are well known in the art and include, but are not limited to, acrylic and methacrylic esters of polyhydric alcohols such as trimethylolpropane, pentaerythritol, and the like; and acrylate or methacrylate terminated epoxy resins, acrylate or methacrylate terminated polyesters, etc. Representative examples include, but are not limited to, ethylene glycol diacrylate, ethylene glycol dimethacrylate, trimethylolpropane triacrylate (TMPTA), pentaerythritol tetraacrylate, pentaerythritol tetramethacrylate, dipentaerythritol hydroxypentacrylate (DPHPA), hexanediol-1,6-dimethacrylate, and diethyleneglycol dimethacrylate. Preferred examples include, but are not limited to, a urethane acrylate or a urethane methacrylate.

A photohardenable resin component can optionally comprise one or more multifunctional acrylate monomers. Dipentaerythritol pentaacrylate, a pentafunctional acrylic monomer available from Sartomer as SR399 is an example of a photohardenable resin component that may be desirable for inclusion in photohardenable composition of the present invention.

Aliphatic urethane acrylates may also be desirable for use as a photohardenable resin component for inclusion in a photohardenable composition described herein.

Mixtures of multifunctional acrylate monomers, such as dipentaerythritol pentaacrylate (e.g., SR399 from Sartomer), and aliphatic urethane acrylates can also be used.

A photohardenable resin component including other mixtures including one or more resin components can also be useful.

Preferably, the photohardenable resin component included in a photohardenable composition is selected to achieve an optically transparent medium, which is desirable in processes and systems in which light, e.g., excitation light, is directed into the composition or light.

Examples of particularly preferred photohardenable resin components include, but are not limited to, free-radical-polymerizable resins, cross-linkable resins, multifunctional acrylate monomers, methacrylates, aliphatic urethane acrylates, and the like.

Optionally a solvent, preferably, for example, but not limited to, an acrylamide monomer or an acrylate monomer, can be further included in a composition described herein for mixing the photoswitchable photoinitiator in the photohardenable resin component. Other suitable solvents may also be used.

A photohardenable composition can optionally include a coinitiator. (A coinitiator can also be referred to as a synergist). Optionally, one or more coinitiators can be included.

Suitable coinitiators include coinitiators which are reducing agents, oxidizing agents, or hydrogen donating compounds.

Examples of coinitiators that may be useful can be selected from among those known in the art and, more particularly, tertiary amines and organoborate salts. Iodonium salts may also be useful, particularly in combination with a borate salt. In certain embodiments, an iodonium salt may also be included in combination with a tertiary amine. Examples of other useful electron donating coinitiators are discussed by Eaton, D. F., “Dye Sensitized Photopolymerization”, Advances in Photochemistry, Vol. 13, pp 427-486.

Representative examples of N,N-dialkylanilines useful in the present invention as coinitiators include 4-cyano-N,N-dimethylaniline, 4-acetyl-N,N-dimethylaniline, 4-bromo-N,N-dimethylaniline, 4-methyl-N, N-dimethylaniline, 4-ethoxy-N,N-dimethylaniline, N,N-dimethylthioanicidine, 4-amino-N,N-dimethylaniline, 3-hydroxy-N, N-dimethylaniline, N,N,N,′N,-tetramethyl-1,4-dianiline, 4-acetamido-N,N-dimethylaniline, 2,6-diethyl-N,N-dimethylaniline, N,N,2,4,6-pentanethylaniline (PMA) and p-t-butyl-N,N-dimethylaniline.

Certain other tertiary amines are also useful coinitiators including triethylamine, triethanolamine, N-methyldiethanolamine, 2-ethyl-4-(dimethylamino)benzoate, 2-ethylhexyl-4-(dimethylamino)benzoate, etc.

Another class of useful coinitiators includes alkyl borate salts such as ammonium salts of borate anions of the formula BR^{a}R^{b}R^{c}R^{d} wherein R^{a}-R^{d} are independently selected from the group consisting of alkyl, aryl, alkaryl, allyl, aralkyl, alkenyl, alkynyl, alicyclic and saturated or unsaturated heterocyclic groups. Representative examples of alkyl groups represented by R^{a}-R^{d} are methyl (Me), ethyl, propyl, butyl, pentyl, hexyl, octyl, stearyl, etc. The alkyl groups may be substituted, for example, by one or more halogen, cyano, acyloxy, acyl, alkoxy or hydroxy groups. Representative examples of aryl groups represented by R^{a}-R^{d} include phenyl, naphthyl and substituted aryl groups such as anisyl and alkaryl such as methylphenyl, dimethylphenyl, etc. Representative examples of aryl groups represented by R^{a}-R^{d} include benzyl. Representative alicyclic groups include cyclobutyl, cyclopentyl, and cyclohexyl groups. Examples of an alkynyl group aryl propynyl and ethynyl, and examples of alkenyl groups include a vinyl group. Preferably, at least one but not more than three of R^{a}, R^{b}, R^{c}, and R^{d} is an alkyl group. Each of R^{a}, R^{b}, R^{c}, and R^{d} can contain up to 20 carbon atoms, and they typically contain 1 to 7 carbon atoms. More preferably R^{a}-R^{d} are a combination of alkyl group(s) and aryl- group(s) or aralkyl group(s) and still more preferably a combination of three aryl groups and one alkyl group, i.e., an alkyltriphenylborate, e.g., but not limited to, a butyltriphenyl borate.

A photohardenable composition can optionally include a sensitizer. Optionally, one or more sensitizers can be included.

A sensitizer can create the excited state of the photoswitchable photoinitiator via absorbing light and transferring energy to the photoswitchable photoinitiator. For example, a sensitizer can control the sensitivity of the composition and extend the spectral sensitivity of the closed form of the photoswitchable photoinitiator. Useful sensitizers include those known in the art such as acetophenone, benzophenone, 2-acetonaphthone, isopropyl thioxanthone, alkoxyketocoumarins, Esacure 3644, and the like.

Optionally, a composition described herein can include one or more coinitiators and one or more sensitizers.

A photohardenable composition for use in the methods of the present invention preferably display non-Newtonian rheological behavior. Such rheological behavior can facilitate forming an object in a volume of a photohardenable composition upon exposure to at least two different wavelengths of excitation light wherein the object remains at a fixed position or is minimally displaced in the volume of the unhardened composition during formation. Minimal displacement refers to displacement of the object being formed during its formation in the volume that is acceptable for precisely producing the intended part geometry. Such rheological behavior can also facilitate separation of the partially hardened object from the volume in which it is formed upon application of stress. While not wishing to be bound by theory, upon the application of stress, the apparent viscosity of the non-Newtonian composition can drop to a lower value (e.g., the steady shear viscosity) than the static value (e.g., zero shear viscosity or yield stress) allowing the unhardened composition to more easily flow off and separate from the object. Examples of such non-Newtonian rheological behavior include but are not limited to pseudoplastic fluid, yield pseudoplastic, Bingham plastic, Bingham pseudoplastic rheological behavior.

Non-Newtonian rheological behavior can be imparted to a photohardenable composition by further including one or more reactive components (e.g. urethane acrylate oligomers, urethane methacrylate oligomers, acrylated or methacrylated polyurethanes, acrylated or methacrylated polyurethane-ureas, acrylated or methacrylated polyesters, acrylated or methacrylated polyamides, acrylate- or methacrylate-functional block copolymers, alkenyl- or alkynyl-functional urethane oligomers, alkenyl- or alkynyl-functional polyurethanes, alkenyl- or alkynyl-functional polyurethane-ureas, alkenyl- or alkynyl-functional polyesters, alkenyl- or alkynyl-functional polyamides, alkenyl- or alkynyl-functional block copolymers, thiol-functional urethane oligomers, thiol-functional polyurethanes, thiol-functional polyurethane-ureas, thiol-functional polyesters, thiol-functional polyamides, thiol-functional block copolymers) in the photohardenable resin component and/or by further adding one or more nonreactive additives (e.g., but not limited to, one or more thixotropes and/or rheology modifiers) to the composition. Selection of the one or more of reactive components and the amounts thereof for addition to a photohardenable resin component included in a photohardenable composition to impart non-Newtonian rheological behavior thereto is within the skill of the skilled artisan in the relevant art without undue experimentation. Similarly, selection of nonreactive additives and the amount(s) thereof for addition to the photohardenable composition to impart non-Newtonian rheological behavior thereto is within the skill of the skilled artisan of the relevant art without undue experimentation.

A photohardenable composition described herein can preferably have a steady shear viscosity, for example, which is less than 30,000 centipoise, less than 20,000 centipoise, less than 10,000 centipoise, less than 5,000 centipoise, less than 1,000 centipoise. (Steady shear viscosity refers to the plateau value of the viscosity achieved with unidirectional constant shear, e.g., the value of the viscosity after the thixotrope network has broken up.) Steady shear viscosities may be measured at ambient (e.g., room temperature), printing temperature, or some other temperature (e.g., elevated or reduced). Measurement at printing temperature may provide advantage in determining the suitability of a photohardenable composition for printing. Preferred steady shear viscosities are less than 30,000 centipoise, more preferably less than 10,000 centipoise, and most preferably less than 1,000 centipoise.

Steady shear viscosity can be measured under continuous constant-rate shear, such as at shear rates ranging from about 0.00001 s⁻¹ to about 1000 s⁻¹.)

Photohardenable compositions can further include one or more additives. Examples of additives include, but are not limited to, a filler, a thixotrope/rheology modifier, a defoamer, a stabilizer, an oxygen scavenger, a non-reactive solvent diluent, a thermally activated radical initiator, and a colorant. Any additive can be a single additive or a mixture of additives. For example, a thixotrope can comprise a single thixotrope or a mixture of two or more thixotropes. Additional information concerning additives and non-limiting examples thereof are provided below.

Additives are preferably selected so that they do not react with other components or additives that may be included in photohardenable compositions.

### Fillers

As mentioned above, one example of an additive that may be included in photohardenable compositions includes a filler. Optionally a filler can include a combination of one or more fillers. A fillers can be included in an amount greater than 0 to about 90 weight percent, the amount being determined by the purpose for the filler and the desired end use characteristics for the intended three-dimensional object. Advantageously, fillers may be selected to maintain the optical transparency of the photohardenable composition, e.g., by controlling particle size to be substantially less than the excitation wavelengths or by matching the refractive indices of the filler and matrix to reduce optical scatter.

Fillers may be used to modify the properties of a hardened photohardenable composition, for example the stiffness, strength, toughness, impact resistance, resistance to creep, resistance to fatigue, mechanical energy return, mechanical loss tangent, glass transition temperature, thermal degradation temperature, thermal conductivity, thermal resistance, moisture uptake, electrical conductivity, static dissipation, dielectric constant and loss tangent, density, refractive index, optical dispersion, opacity to ionizing radiation, and resistance to ionizing radiation. Fillers may also be used to modify the properties of the liquid (e.g., unhardened) photohardenable composition, such as rheological properties such as viscosity and thixotropy and optical properties such as refractive index. Examples of fillers include but are not limited to silica, alumina, zirconia; silicates glasses such as soda-lime glass, borosilicate glass, sodium silicate glass, lead glass, aluminosilicate glass, barium glass, thorium glass, glass ceramics; chalcogenide glasses; glass microspheres and microbubbles; nanoclays such as laponite, montmorillonite, bentonite, kaolinite, hectorite, and halloysite; calcium phosphate minerals such as hydroxyapatite, mineral fillers such as chalk, rock dust, slag dust, fly ash, hydraulic cement, loess, limestone, kaolin, talc, and wollastonite. Examples of particle size ranges include but are not limited to less than 10 microns, less than 1 micron, 10 nm to 500 nm, 10 nm to 90 nm, 40 nm to 70 nm. Smaller particles sizes, in particular sizes less than about 100 nm, may be beneficial to provide high optical clarity of the liquid composition to better facilitate printing. Controlling the particle size distribution, for example monodisperse, bimodal, or trimodal distributions of sizes, may be beneficial to control rheological properties, increase filler weight percent, or modify the properties of a photohardenable composition.

### Thixotrope/Rheology Modifier

Other examples of additives that may be included in photohardenable compositions include a thixotropes and rheology modifiers. Thixotropes and rheology modifiers suitable for inclusion in a photohardenable composition described herein include, for example and without limitation, urea derivatives; modified urea compounds such as Rheobyk 410 and Rheobyk-D 410 available from BYK-Chemie GmbH, part of the ALTANA Group; fumed metal oxides (also referred to as pyrogenic metal oxides) including for example, but not limited to, fumed silica, fumed alumina; zirconia; precipitated metal oxides including for example, but not limited to, precipitated silica, precipitated alumina; unmodified and organo-modified phyllosilicate clays; dimer and trimer fatty acids; polyether phosphates; oxidized polyolefins; hybrid oxidized polyolefins with polyamide; alkali soluble/swellable emulsions; cellulosic ethers; hydrophobically-modified alkali soluble emulsions; hydrophobically-modified ethylene oxide-based urethane; sucrose benzoate; ester terminated polyamides; tertiary amide terminated polyamides; polyalkyleneoxy terminated polyamides; polyether amides; acrylamidomethyl-substituted cellulose ester polymers; polyethyleneimine; polyurea; organoclays; hydrogenated castor oil; organic base salts of a clay mineral (e.g., montmorillonite) and other silicate-type materials; aluminum, calcium, and zinc salts of fatty acids, such as lauric or stearic acid.

See U.S. Pat. No. 6,548,593 of Merz, et al., issued Apr. 15, 2003, and U.S. Pat. No. 9,376,602 of Walther, et al. issued Jun. 28, 2016, which are hereby incorporated herein by reference in their entireties, for information relating to urea derivatives that may be useful as thixotropes.

Thermally reversible gellants such as ester terminated polyamides, tertiary amide terminated polyamides, polyalkyleneoxy terminated polyamides, and polyether amides, and combinations thereof, may be desirable for us as thixotropes. Examples include Crystasense LP1, Crystasense LP2, Crystasense LP3, Crystasense MP, Crystasense HP4, Crystasense HP5, Rheoptima X17, Rheoptima X24, Rheoptima X38, Rheoptima X58, Rheoptima X73, and Rheoptima X84 available from Croda. Crystasense HP-5 is a preferred example of a thixotrope. Metal oxides that have been surface-treated to impart dispersibility characteristics compatible with a photohardenable composition described herein may be desirable for use as thixotropes.

A thixotrope can be included in a photohardenable composition in an amount, for example, in a range from about 0.05 weight percent to about 15 weight percent, from about 0.5 weight percent to about 15 weight percent, from about 0.5 weight percent to about 10 weight percent from about 1 to about 10 weight percent of the composition. Other amounts may also be determined to be useful.

A thixotrope is preferably included in a photohardenable composition in an amount effective to restrict movement of the three-dimensional object or one or more regions thereof in the photohardenable composition during formation.

More preferably, the thixotrope is included in a photohardenable composition in an amount effective to restrict movement of the three-dimensional object suspended (without contact with a container surface) in the volume of composition during formation. Most preferably the position of the object in the volume of the photohardenable composition remains fixed position during formation of the object.

### Defoamer

Another example of additives that can be included in a photohardenable composition includes defoamers. A defoamer can be included to aid in removing bubbles introduced during processing and handling. A preferred defoamer is BYK 1798 (a silicone based defoamer) available from BYK-Chemie GmbH, part of the ALTANA Group.

### Stabilizer

Another example of additives that can be included in a photohardenable composition includes a stabilizer. A stabilizer can be included to improve shelf-life of the composition and/or to control the level of cure and/or spatial resolution during printing. An example of preferred stabilizer is TEMPO (2,2,6,6-tetramethylpiperidinooxy free radical available from Sigma-Aldrich). Examples of other stabilizers include, but are not limited to, hindered phenols such as butylated hydroxytoluene; hydroquinone and its derivatives such as hydroquinone methyl ether; hindered amine light stabilizers; alkylated diphenylamines; and phosphite esters.

### Oxygen Scavenger

Another optional additive that can be included in a photohardenable composition includes an oxygen scavenger that can be included to react with oxygen (e.g., singlet oxygen, dissolved oxygen) present in the composition.

Optionally an additive comprising a non-reactive solvent diluent can be included. Examples include, but are not limited to, acetone, amyl acetate, n-butanol, sec-butanol, tert-butanol, butyl acetate, cyclohexanone, decane, dimethylacetamide, dimethylformamide, dimethylsulfoxide, dipropylene glycol, dipropylene glycol methyl ether, ethanol, ethyl acetate, ethylene glycol, glycerol, heptane, isopropanol, isopropyl acetate, methyl ethyl ketone, N-methyl pyrrolidone, propylene carbonate, propylene glycol, propylene glycol diacetate, tetrahydrofuran, tripropylene glygol methyl ether, toluene, water, xylenes.

### Thermally Activated Radical Initiator

It may also be desirable to include a thermally activated radical initiator in a photohardenable composition. Thermally activated radical initiator examples include but are not limited to 2,2′-azobis(2-methylpropionitrile), 1,1′-azobis(cyclohexanecarbonitrile), 2,2′-azobis[N-(2-carboxyethyl)-2-methylpropionamidine] n-hydrate, 2,2′-azobis[2-methyl-N-(2-hydroxyethyl)propionamide], organic peroxides, inorganic peroxides, peroxydisulfate salts.

Unless otherwise indicated, specified weight percents are based on the total weight of the photohardenable composition.

The nature of a photohardenable resin component, the amount of the dual wavelength, and, when applicable, a coinitiator, a sensitizer, a thermally activated radical initiator, or other optional additive, included in photohardenable compositions will vary with the particular use of the compositions, the emission characteristics of the exposure sources, the development procedures, the physical properties desired in the hardened product and other factors.

Examples of photohardenable compositions in accordance with certain aspects of the invention including one or more coinitiators and/or sensitizers will generally have compositions which fall within the following compositional ranges in parts by weight [based on 100 parts total]:
Photoswitchable photoinitiator: about 0.0001 to about 0.5, including, for example, but not limited to, about 0.0001 to about 0.1, about 0.0001 to about 0.05, about 0.0001 to about 0.02, about 0.0001 to about 0.01, about 0.0001 to about 0.009, about 0.0001 to about 0.005, from about 0.0001 to about 0.0025, etc.
Coinitiators (optional) about 0.001 to about 10 including, for example, but not limited to, about 0.001 to about 7.5, about 0.001 to about 5, about 0.001 to about 2.5, about 0.001 to about 1, about 0.001 to about 0.5, from about 0.001 to about 0.25, etc.
Sensitizer (optional) about 0.1 to about 1, including, for example, but not limited to, about 0.1 to about 0.75, about 0.1 to about 0.5, about 0.1 to about 0.25, etc.
Photohardenable resin component—the balance of the photohardenable composition

Examples of photohardenable compositions in accordance with certain aspects of the invention not including one or more coinitiators and/or sensitizers will generally have compositions which fall within the following compositional ranges in parts by weight [based on 100 parts total]:
Photoswitchable photoinitiator: about 0.0001 to about 0.5, including, for example, but not limited to, about 0.0001 to about 0.1, about 0.0001 to about 0.05, about 0.0001 to about 0.02, about 0.0001 to about 0.01, about 0.0001 to about 0.009, about 0.0001 to about 0.005, from about 0.0001 to about 0.0025, etc.
Photohardenable resin component—the balance of the photohardenable composition.

The weight percent of the photohardenable resin component in the above exemplary compositions can be less than 10 weight percent, e.g., less than five weight percent, less than 3 weight percent, less than 2 weight percent, or one weight percent or less, in some cases such as printing of hydrogels where the remainder of the resin is then comprised of non-reactive components that are suspended within the final photohardened resin.

The above describes compositions and compositional ranges for non-limiting examples of photohardenable compositions in accordance with the invention. Variations of the above examples of the photohardenable composition described herein and compositional ranges for the constituents included therein may also be determined to be suitable and within the scope of the present invention.

Optionally, a photohardenable composition can further include a second light activated photoinitiator. Preferably such photoinitiator is not appreciably responsive to light of a first wavelength or second wavelength. Inclusion of a photoinitiator can be desirable in connection with optional post-processing that includes, for example, a post-curing step involving exposure of the printed object to UV light after printing.

If a second light-activated photoinitiator is included in a photohardenable resin composition, the method can further include a post curing step comprising exposing the object to light of a third wavelength to further harden the object, the third wavelength being different from the first and second wavelengths. Irradiation with the third wavelength is preferably carried out after the partially hardened part is removed or separated from the volume in which it is formed. It can also be desirable to wash the separated or removed part prior to post-cure irradiation with the third wavelength. When the second light activated photoinitiator is UV activatable, the third wavelength is preferable in the ultraviolet range of wavelengths. A third wavelength in a range, for example, from about 240 to about 455 nm, about 240 nm to about 445 nm, from about 240 nm to about 410, or other ranges that are less than the first and second wavelengths can be useful.

Selection of a second photoinitiator is generally made taking into consideration the absorption band of the second photoinitiator and the wavelength of the radiation or light that will be used to activate the second photoinitiator and the first and second wavelengths for activating the photoswitchable photoinitiator so that undesired polymerization is avoided. By way of non-limiting examples, second photoinitiators are available that can be activated by UV or visible wavelength light. Other factors, e.g., absorption coefficients, rate constants of the primary radicals toward the photohardenable resin component, possible side reactions, light intensity can also be taken into consideration and balanced in the selection process. See, for example, A, Eibel, et al., “Choosing the ideal photoinitiator for free-radical photopolymerizations: predictions based on simulations using established data”, Polym. Chem., 2018, 9, 5107-5115.

It is desirable for the second photoinitiator to show no or minimal absorption of the first wavelength and the second wavelength.

Preferably the third wavelength is not directed into the volume during formation of the partially hardened object therein.

Preferably the third wavelength is less than the first and second wavelengths.

The second photoinitiator preferably comprises a photoinitiator that initiates polymerization or cross-linking of the photohardenable resin component by free-radical reactions (also referred to herein as a free-radical photoinitiator). A second photoinitiator can comprise a Type I photoinitiator. (A Type I photoinitiator may also be referred to in the art as a Norrish Type I photoinitiator.) A second photoinitiator can comprise a Type II photoinitiator. (A Type II photoinitiator may also be referred to in the art as a Norrish Type II photoinitiator.) A second photoinitiator comprising a single component, e.g., a Type I photoinitiator, which does not appreciably absorb light at the first or second wavelength, can be preferred.

Examples of second photoinitiators include, but are not limited to, acetophenone, anisoin, anthraquinone, benzil, benzoin, benzoin ethyl ether, benzophenone, 1-hydroxycyclohexyl phenyl ketone, 2-benzyl-2-(dimethylamino)-4′-morpholinobutyrophenone, 4,4′ bis(diethylamino) benzophenone, thioxanthone, 2-chlorothioxanthone, dibenzosuberenone, 2,2′-diethoxyacetophenone, 4,4′ dihydroxybenzophenone, 2,2-dimethoxy-2-phenylacetophenone, diphenyl(2,4,6 trimethylbenzoyl) phosphine oxide (TPO), 4′-ethoxyacetophenone, 3′-hydroxyacetophenone, 4′-hydroxyacetophenone, 3-hydroxybenzophenone, 1-hydrocyclohexyl phenyl ketone, 2-hydroxy-2-methylpropiophenone, methylbenzoylformate, 2-methyl-4′-(methylthio)-2-morpholinopriopiophenone, phenanthraquinone, 4′-phenoxyacetophenone.

An example of preferred second photoinitiator comprising a free-radical photoinitiator is Omnirad 184 (1-hydroxycyclohexyl-phenyl ketone) available from IGM.

Exposure of the second photoinitiator to light at the third wavelength can advantageously induce alteration or alter, typically by a crosslinking or polymerization reaction in the photohardenable composition, at least one chemical or physical property of previously unaltered photohardenable composition included in the object for further hardening of the initial print or partially hardened object.

Preferably the second photoinitiator shows no or minimal absorption of the first wavelength and the second wavelength.

It can be desirable for the second photoinitiator not to be activatable or appreciably activatable by the first or second wavelengths to avoid undesired reactions in the photohardenable composition in the absence of exposure to the third wavelength.

Post-curing of an initial print or partially hardened object can be carried out with third wavelength light for further hardening (e.g., for further polymerization or cross-linking).

Preferably exposure to the third wavelength is carried out after separation of the partially hardened object from the volume in which it is formed. It can be desirable to wash the separated object prior to irradiating it with light of the third wavelength.

Examples of amounts of the second light activated photoinitiator that can be included in a photohardenable composition include, but are not limited to, from about 0.0001 to about 25, weight percent second light activated photoinitiator based on the weight of the photohardenable composition.

See International Application No. PCT/US2023/022171, filed May 13, 2023, of Quadratic 3D, Inc. for additional information relating to inclusion of a second light activated photoinitiator in a photohardenable composition.

Optionally, a photohardenable composition can further include a resin component that is hardenable by a thermally driven reaction or mechanism, the resin component comprising a monomer, an oligomer, a pre-polymer, a polymer, or a mixture including at least one the foregoing.

Inclusion of one or more resin components that can be hardened by a thermally driven reaction or mechanism in a photohardenable resin composition can facilitate or enable formation of articles with characteristics and/or performance properties that can be suitable for end-use applications for articles formed from a resin including a photohardenable composition without the resin component may not be suitable. Examples of added properties that may be modified by the inclusion of the second resin component include, for example, but are not limited to, mechanical, thermal, electrical, dielectric, chemical resistance, moisture resistance, and biocompatibility properties. Examples include improved mechanical properties including increased tensile strength and modulus, flexural strength and modulus, compressive strength and modulus, impact strength, hardness, wear resistance, fatigue resistance, fracture toughness; improved thermal properties including increased glass transition temperature, increased heat deflection temperature, increased thermal degradation temperature, or reduced coefficients of thermal expansion; reduced moisture or solvent uptake; improved radiation resistance; improved fire resistance, flame retardancy, or char yield; improved dielectric performance (e.g., reduced dielectric constant, reduced dielectric loss constant, or increased breakdown voltage); or improved optical properties (e.g., increased refractive index).

Examples of suitable resin components include, but are not limited to, polyurethane, polyurethane-urea, and polyurea precursors; epoxy resins and epoxy curing agents; cyanate ester resins and phthalonitrile resins; maleimide resins such as bismaleimide resins, alone or with allyl curing agents; polyimide and polyamide imide precursors including but not limited to polyamic acids (e.g. poly(pyromellitic dianhydride-co-4,4′-oxydianiline) amic acid), polyamide amic acids (e.g., Torlon AI-30 and Torlon AI-50 available from Solvay), amines, acid anhydrides, and isocyanates; norbornene resins such as nadic-anhydride-terminated resins; phenolic resins; and benzoxazine resins.

A photohardenable composition further including a hardenable resin component can include, for example, but without limitation, from about 0.5 to about 95, preferably from about 40 to about 95, weight percent photohardenable resin component; from about 0.0001 to about 0.05, preferably from about 0.0001 to about 0.02 weight percent photoswitchable photoinitiator; and from about 0.5 to about 95, and preferably from about 15 to about 95, weight percent resin component.

See International Application No. PCT/US2023/022171, filed May 13, 2023, of Quadratic 3D, Inc. for additional information relating to further inclusion of a hardenable resin component in a photohardenable composition.

The methods in accordance with various aspects of the invention can further include post-treatment of the three-dimensional object(s) formed.

Examples of post-treatments include, but are not limited to, removing the formed three-dimensional object from the container. Following removal from the container, the completed object can be further processed. Examples of further processing include, without limitation, washing, post-curing (e.g., by light, e-beam, heat, non-ionizing radiation, ionizing radiation, time (aging), pressure, humidity, or simultaneous or sequential combinations of techniques), metrology, labelling or tracking (e.g., by barcode, QR code, or RFID tag), freeze-dry processing, critical point drying, and packaging.

In methods in accordance with the invention for forming a three-dimensional object including a composition described herein that includes a photoswitchable photoinitiator, it is desirable to select a photoswitchable photoinitiator molecule for which the wavelength of first excitation has significant absorption for the first form, and where the second form of the photoinitiator has minimal absorption of the first excitation wavelength. This has two advantages, first, it simplifies exposure in that activation of the photoswitchable photoinitiator can occur without activating the second form thereof to alter, typically by a crosslinking or polymerization reaction in the photohardenable resin component included in the composition, at least one chemical or physical property of the photohardenable resin component included therein. When there is substantial overlap, the intensity of the two radiations must be carefully controlled so as to activate the photoswitchable photoinitiator molecule while minimally activating the second form thereof. Second, it can permit deeper penetration of the volume or layer of the composition as the conversion of the photoswitchable photoinitiator to the second form thereof has the effect of “bleaching” the photoswitchable photoinitiator molecule or making it transparent with respect to the first wavelength radiation.

Preferably photoswitchable photoinitiators useful in methods for printing 3D objects in accordance with the present invention can absorb first wavelength light from about 300 nm to about 550 nm. Other examples of ranges in which the photoswitchable photoinitiator will absorb first wavelength light include, but are not limited to, from about 350 to about 460 nm, from about 350 to about 455 nm, from about 350 nm to about 445 nm, from about 350 nm to about 410 nm, from about 375 to about 455 nm, from about 375 to about 445 nm, from about 375 nm to about 405 nm. Other examples are described herein. Depending upon the extinction coefficient for the particular photoswitchable photoinitiator, the conversion to the second form can be induced by exposure to any source which emits in this range, e.g., lasers, light emitting diodes, mercury lamps. Filters may be used to limit the output wavelengths. A non-limiting example of filtered light includes filtered emission from a mercury arc lamp, etc. Lasers can be preferred sources of radiation for generating radiation of the first wavelength.

The second form of the photoswitchable photoinitiator will preferably absorb second wavelength light in a range of about 450 nm to about 1000 nm, and from about 450 nm to about 850 nm most typically. Other examples of ranges in which the second form of the photoswitchable photoinitiator will preferably absorb second wavelength light include from about 450 nm to about 700 nm. This form can be activated by the second excitation light to produce free radicals directly or to produce excitons which undergo electron transfer or hydrogen abstraction (optionally via electron, hydrogen, or energy transfer to coinitiator(s) in aspects of the invention including one or more coinitiator) by exposure to any second wavelength within this range. For the second excitation, exposures may be accomplished using a laser source, an LED or LED array, the filtered emission from an arc lamp, or other suitable source with emission within the desired wavelength range. argon ion, He-Ne, laser diodes, krypton, frequency-multiplied Nd-YAG etc. Other light sources may be used, optionally with filters to limit output wavelengths, e.g., light emitting diodes, incandescent lamps, halogen lamps, mercury lamps, arc lamps, etc. Lasers can be preferred sources of radiation for generating radiation of the second wavelength.

As used herein a wavelength can refer to a wavelength or range of wavelengths.

Optically transparent portions of a container can be constructed from a material comprising, for example, but not limited to, glass, quartz, fluoropolymers (e.g., Teflon FEP, Teflon AF, Teflon PFA), cyclic olefin copolymers, polymethyl methacrylate (PMMA), polynorbornene, sapphire, or transparent ceramic.

Examples of container shapes include, but are not limited to, a cylindrical container having a circular or oval cross-section, a container having straight sides with a polygonal cross-section or a rectangular or square cross-section.

Preferably the optically transparent portion(s) of the container is (are) also optically flat.

Optionally, one or more filters can be added to at least a surface of any optically transparent portions of the container to block undesired light, e.g., room light, to prevent unintentional curing.

Optionally a printing compositions (e.g., a photohardenable composition can be filtered to remove particulates before introduction into the container. Optionally bubbles are removed from the photohardenable composition before or after being introduced into the container.

The method disclosed herein can also include the use of commercially available projection and filtering techniques that can assist in providing a very narrow depth of focus.

Excitation light may be visible light, ultraviolet light, or other suitable forms of electromagnetic radiation.

In methods described herein, each wavelength is preferably generated by a different light source or different optical projection or other optical systems.

The radiation or excitation source is preferably selected to emit radiation at a wavelength or within a range of wavelengths absorbed by the particular photoinitiator, e.g., the photoswitchable photoinitiator.

Excitation light or radiation may be applied using any suitable light or electromagnetic radiation source or optical system (which typically includes a light or electromagnetic radiation source). Examples of light or electromagnetic radiation light sources include, but are not limited to, lasers (including laser diodes) and other coherent light sources, light-emitting diodes (LEDs), micro-LED arrays, vertical cavity lasers (VCLs), and filtered lamps. Such light sources are commercially available and selection of a suitable light source can be readily made by one of ordinary skill in the relevant art. LEDs of the type such as Phlatlight LEDs available from Luminus for use with DMDs may also be suitable. Lasers can be preferred sources of radiation for generating radiation of the first, the second, the third and, if applicable, the fourth wavelengths.

Examples of projection devices suitable for use in the methods described herein may include, but are not limited to, a laser projection system, a liquid crystal display (also referred to herein as “LCD”), a spatial light modulator (also referred to herein as “SLM”) (for example, but not limited to, a digital micromirror device (also referred to herein as “DMD”)), a micro-LED array, a vertical cavity laser array (also referred to herein as “VCL”), a Vertical Cavity Surface Emitting Laser array (also referred to herein as “VCSEL”), a liquid crystal on silicon (also referred to herein as “LCOS”) projector, and a scanning laser system. (Light emitting diode is also referred to herein as “LED”).

A light sheet can be constructed by means known in the art including, for example, but not limited to, techniques including a laser and a Powell lens, galvanometer, and/or polygon scanning mirror. Alternatively, one or more LEDs can be used as a light source.

Spatially modulated excitation light can be used to direct or irradiate a patterned image or a two-dimensional image. For example, spatially modulated excitation light can be created by an optical projection system including a spatial modulation component (also referred to herein as a spatial light modulator (“SLM”)). Examples of spatial modulation components for inclusion in an optical projection system include, for example and without limitation, a liquid crystal display (also referred to herein as “LCD”), a digital micromirror device (also referred to herein as “DMD”)), a micro-LED array, a vertical cavity laser (also referred to herein as “VCL” or as a Vertical Cavity Surface Emitting Laser (also referred to herein as “VCSEL”), a scanning laser system, a liquid crystal on silicon (also referred to herein as “LCOS”) microdisplay.

An optical system for generating and projecting an optical image can include a light source, projection optics, and a spatial modulation component.

Optionally, the excitation light can be temporally and/or spatially modulated. Optionally, the intensity of the excitation light can be modulated by known or readily ascertainable techniques. Optionally, source drive modulation by known or readily ascertainable techniques can be used to adjust the absolute power of the light beam.

An optical system can be selected to apply continuous excitation light. An optical system can be selected to apply intermittent excitation light. Intermittent excitation can include random on and off application of light or periodic application of light. Examples of periodic application of light includes pulsing. An optical system can be selected to apply a combination of both continuous excitation light and intermittent light, including, for example, an irradiation step that includes the application of intermittent excitation light that is preceded or followed by irradiation with continuous light.

An optical projection system can further include one or more additional components including, but not limited to, one or more translational stages for moving the system or components thereof.

In methods described herein, power densities or intensities of excitation light directed into the volume of photohardenable composition to cause partial hardening (e.g., by polymerization, crosslinking) to occur at the one or more selected locations may be, without limitation, in a range from about 0.01 to about 100,000 W/cm².

Other power densities or intensities may also be determined to be useful.

In the methods described herein, the container optionally may be rotated to provide additional angles of illumination or projection of excitation light into the volume of photohardenable composition contained therein. This can be of assistance in patterning object volumes or surfaces more accurately or it can be used as a means of providing multiple exposure of a given feature from different angles.

In the method described herein, the container optionally may be stationary while a beam or optical projection of excitation light is being directed into the volume of the printing composition. Alternatively, the position of the container may be translated or moved during excitation while a beam and/or optical projection of excitation is being directed into the volume of the printing composition.

As discussed above, before assigning intensity levels to pixels to be illuminated in an optical image, a digital file of the object or object to be printed is obtained. If the digital file is not of a format that can be used to print the object, the digital file is then converted to a format that can be used to print the object. An example of a typical format that can be used for printing includes, but is not limited to, an STL file. Typically, the STL file is then sliced into two-dimensional layers with use of three-dimensional slicer software and converted into G-Code or a set of machine commands, which facilitates building the object. See B. Redwood, et al., “The 3D Printing Handbook—Technologies, designs applications”, 3D HUBS B.V. 2018.

Other information concerning optical systems that may useful in connection with the various aspects of the present inventions includes Texas Instruments Application Report DLPA022-July 2010 entitled “DLP™ System Optics”; Texas Instruments “TI DL^{R}Technology for 3D Printing—Design scalable high-speed stereolithography [sic] systems using TI DLP technology” 2016; Texas Instruments “DLP6500 0.65 1018p MVSP Type A DMD”, DLP6500, DLPS040A-October 2014—Revised October 2016; and Y-H Lee, et al., “Fabrication of Periodic 3D Nanostructuration for Optical Surfaces by Holographic Two-Photon-Polymerization”, Int'l Journal of Information and Electronics Engineering, Vol 6, No. 3, May 2016, each of the foregoing being hereby incorporated herein by reference in its entirety.

“Intensity”, as it relates to excitation light, is also referred to herein as brightness or power density.

The 3D printing method described herein does not require adhering the object being printed to a fixed substrate (e.g., build plate) at the beginning of the printing process avoiding a post-processing step of separating the printed object from the fixed substrate. It additionally facilitates printing three-dimensional objects in a volume of photopolymerizable liquid without requiring support structures to form a printed object. Post-processing steps of removing support structures and/or removing the printed object from a fixed substrate add labor (e.g., manual removal), waste (discarded support structures), and reduce throughput (a build plate cannot be reused until the printed object is removed), all of which add cost to the process.

When used as a characteristic of a portion of a container or build chamber, “optically transparent” refers to having high optical transmission to the wavelength of light being used, and “optically flat” refers to being non-distorting (e.g., optical wavefronts entering the portion of the container or build chamber remain largely unaffected).

As used herein, the singular forms “a”, “an” and “the” include plural unless the context clearly dictates otherwise. Thus, for example, reference to an emissive material includes reference to one or more of such materials.

Applicant specifically incorporates the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1-3. (canceled)

4. A method for producing a three-dimensional (3D) object with use of a 3D printer including at least two excitation lights including a first excitation light and a second excitation light, the method comprising:
a) providing a volume including a photohardenable composition comprising a photohardenable component and a dual wavelength photoinitiator wherein exposure of the photohardenable composition to a first excitation light including a first wavelength and a second excitation light including a second wavelength induces a crosslinking or polymerization reaction in the photohardenable composition;
b) generating a scaled model of two-dimensional cross-sectional digital slices of the 3D object to be printed, wherein each cross-sectional digital slice includes an arrangement including a grid of pixels to be illuminated and pixels not to be illuminated during printing of the slice, and wherein generating the scaled model of the digital slice comprises assigning an intensity level to each pixel to be illuminated at a position in the arrangement with the second excitation light based on at least the position in the arrangement of each pixel to be illuminated with the second excitation light relative to one or more propagating rays of the first excitation light to which the pixel will be exposed during printing of the scaled digital slice;
c) exposing a selected two-dimensional cross-sectional plane in the volume of the photohardenable composition to at least a light sheet including the first excitation light comprising the first wavelength and an optical image including the second excitation light comprising second wavelength to form a cross-sectional slice of the 3D object, wherein the optical image comprises a two-dimensional cross-sectional slice of the 3D object generated from a scaled digital slice of the 3D object; and
optionally d) repeating step c) one or more times wherein, for a repeated step, one or both of the selected location and optical image is the same as or different from a previous selected location and/or a previous optical image.

5-7. (canceled)

8. The method of claim 4 wherein the cross-linking or polymerization reaction of the photohardenable composition resulting from exposure to optical image and light sheet at the selected location occurs at a rate that is substantially homogeneous.

9. The method of claim 4 wherein the at least two excitation lights further includes a second light sheet including the first excitation light including the first wavelength, wherein the second light sheet is directed into the volume to overlap the other light sheet, and wherein the intensity levels of illuminated pixels included in the optical image is based on the position in the arrangement of each given illuminated pixel relative to propagating light rays included in each of the two light sheets to which each of the given illuminated pixels is exposed during printing of the scaled digital slice.

10. The method of claim 4 wherein, in assigning an intensity level to a pixel, a row of the of pixels in the grid corresponds to a path traversed by one or more propagating light rays of the first excitation light from a first side edge of the optical image to a second side edge of the optical image to which the pixel is exposed, wherein the first and second side edges of the optical image are opposite one another.

11. The method of claim 10 wherein the one or more pixels illuminated by the second excitation light that are located at one or more positions included in the second edge of the optical image that are farthest from the first edge of the arrangement are assigned a maximum intensity level, and wherein each given pixel illuminated with the second excitation light that is located along the path of the one or more propagating rays of the first excitation light to which the each given pixel along the path is exposed is assigned an intensity level that decreases as the position of the each given illuminated pixel is progressively closer to the first U.S. Patent Application No. Unassigned edge taking into account the number of illuminated pixels along the path between the second edge and the given pixel.

12-15. (canceled)

16. The method of claim 4 wherein generation of the light sheet includes use of a compression lens to decrease light sheet height, and wherein, depending on the position of a given propagating ray in the light sheet, the path of the given propagating light ray is along a set of pixels included in a horizontal row of the grid or along a set of pixels along a diagonal line of pixels in the grid.

17. The method of claim 4 wherein generation of the light sheet includes defocusing to increase light sheet height, and wherein, depending on the position of a given propagating ray in the light sheet, the path of the given propagating light ray is along a set of pixels included in a horizontal row of the grid or along a set of pixels along a diagonal line of pixels in the grid.

18. The method of claim 4 wherein the path of a given propagating light ray included in a light sheet generated with a constant height is along a horizontal row of the grid.

19. The method of claim 16 wherein the path of a given propagating light ray included in a light sheet created with a lens to decrease light sheet height is based on (i) its position in the light sheet, (ii) the size and focal length of the compression lens, and (iii) the position of the lens relative to the optical image.

20. The method of claim 16 wherein the path of a given propagating light ray included in a light sheet is created with defocusing to increase light sheet height.

21-46. (canceled)

47. The method of claim 4 wherein a scaled digital slice is further modified to take into account intensity levels of gray-scale pixels included in the arrangement.

48. The method of claim 4 wherein the intensity levels of the illuminated pixels in a given row are assigned independently from the assignment of the intensity levels to illuminated pixels in a different row.

49-50. (canceled)

51. A method for improving cure rate homogeneity across a light sheet traversal direction through a photohardenable composition, the method comprising:
a) providing a volume including the photohardenable composition, wherein the photohardenable composition includes a dual wavelength photoinitiator;
b) slicing a digital model corresponding to at least a portion of a 3D object into a plurality of two-dimensional sequential slices of the digital model of the 3D object, each digital slice including an arrangement including pixels to be illuminated by the second excitation light during printing of a slice and pixels not to be illuminated by the second excitation light during printing of the slice;
c) generating a scaled model of each digital slice wherein each pixel in a digital slice to be illuminated with the second excitation is assigned an intensity level based on at least its position in the arrangement relative to one or more propagating rays of the first excitation light to which the pixel will be exposed during printing of the scaled digital slice;
d) exposing a selected two-dimensional cross-sectional plane in the volume of the photohardenable composition to at least a light sheet including a first excitation light comprising a first wavelength and an optical image including a second excitation light comprising a second wavelength to form a cross-sectional slice of the 3D object, wherein the optical image comprises the scaled digital slice corresponding to the selected two-dimensional cross-sectional slice of the 3D object generated from the scaled model of the 3D object; and
optionally e) repeating step c) one or more times wherein, for a repeated step one or both of the two-dimensional cross-sectional plane in the volume and the optical image is the same as or different from a previous selected two-dimensional cross-sectional plane in the volume and/or a previous optical image,
wherein the cure rate across a light sheet traversal direction through the photohardenable composition of the cross-sectional slices of the 3D object being printed is more homogeneous than printing without use of the scaled digital slices.

52. The method of claim 51 wherein the cure rate is substantially homogeneous.

53. (canceled)

54. The method of claim 4 wherein, in assigning an intensity level to a pixel, a row of the grid of pixels comprises a line of individual pixels along a path of one or more propagating light rays of the first excitation from a first side edge of the arrangement to an opposite second side edge of the arrangement to which pixels illuminated with the second excitation light will be exposed during printing of the scaled digital slice, and a second factor in generating the scaled digital model of each slice is also based on the number of pixels illuminated with the second excitation light in the row.

55. The method of claim 4 wherein the first excitation light is in the form of a light sheet generated with use of a compression lens to decrease light sheet height, and wherein, depending on the position of a propagating ray in the light sheet, the path of the propagating light ray is along a set of pixels included in a horizontal row of the grid or along a set of pixels along an angled line of pixels in the grid.

56. The method claim 4 further including a third excitation light including a first wavelength wherein the third excitation overlaps the first excitation light from an opposite direction, and wherein the intensity levels of illuminated pixels included in the arrangement is based on the position in the arrangement of each given illuminated pixel relative to propagating light rays included in each of the first and third excitation lights to which each of the given illuminated pixels is exposed in a scaled digital slice.

57. The method of claim 4 wherein light sheet attenuation by the photohardenable composition is not the same for every two-dimensional slice exposed to the first and second wavelengths.
